(19) United States
(12) Patent Application Publication
(10) Pub. No.: US 2016/0064447 A1
(43) Pub. Date: Mar. 3, 2016

(54) SEMICONDUCTOR DEVICE MANUFACTURING METHOD AND SEMICONDUCTOR DEVICE

(71) Applicant: RENESAS ELECTRONICS CORPORATION, Tokyo (JP)

(72) Inventor: Masatoshi KIMURA, Ibaraki (JP)

(21) Appl. No.: 14/833,605

(22) Filed: Aug. 24, 2015

(30) Foreign Application Priority Data
Aug. 27, 2014 (JP) 2014-172686

(51) Int. Cl. H01L 27/146

(52) U.S. Cl. CPC H01L 27/14643; H01L 27/14627; H01L 27/14636; H01L 27/1463; H01L 27/14614; H01L 27/14689; H01L 27/14641; H01L 27/14685

(57) ABSTRACT

The invention improves performance of a solid-state image sensor in which each of the pixels arranged in a pixel array part includes a microlens and plural photodiodes. The locations of the opposing sides between the photodiodes arranged side by side in each pixel are self-alignedly defined by a gate pattern. The location over wiring where the microlens is to be formed is checked and determined using as a superposition mark a check pattern of the same layer as a gate layer.

### CROSS-REFERENCE TO RELATED APPLICATIONS

The disclosure of Japanese Patent Application No. 2014-172686 filed on Aug. 27, 2014 including the specification, drawings and abstract is incorporated herein by reference in its entirety.

### BACKGROUND

The present invention relates to a semiconductor device manufacturing method and a semiconductor device, and more particularly, to a technique effectively applicable to a semiconductor device including a solid-state image sensor and a manufacturing method therefor.

It is known that a solid-state image sensor (picture device) which is included, for example, in a digital camera having an automatic focusing system and which uses an image plane phase difference technique includes pixels each having two or more photodiodes.

In Japanese Unexamined Patent Application Publication Nos. 2013-106194 and 2000-292685 related with an image sensor, a theory of an image plane phase difference detection system is described and it is stated that each pixel includes two photodiodes.

### SUMMARY

It is conceivable that the locations of each semiconductor region and each layer to be formed in a semiconductor device are determined using locations of patterns formed in the semiconductor device as references as follows. For example, photodiodes to be included in a pixel are formed at locations determined using element isolation regions formed over the main surface of the semiconductor substrate as references. On the other hand, the microlens to be formed over the semiconductor substrate via a wiring layer is, in many cases, formed at a location determined using, out of the plural layers of wirings included in the wiring layer, the highest-layer wiring as a reference.

The highest-layer wiring is formed at a location determined using via-holes formed to be thereunder as references. The via-holes are formed at locations determined using wiring formed to be thereunder as a reference. Out of the plural layers of wirings to be included in the wiring layer, the lowest-layer wiring is formed at a location determined using contact holes formed to be thereunder as references. The contact holes are formed at locations determined using gate electrodes formed over the semiconductor substrate as references. The gate electrodes are formed at locations determined using the element isolation regions as references.

As described above, unlike the photodiodes, the microlens is formed based on the results of superposition alignment indirectly repeated for plural layers. Hence, significant misalignment tends to occur between the photodiodes and the microlens. Such misalignment may cause the image sensor to generate an image in a pseudo out-of-focus state.

Other objects and novel features of the present invention will become apparent from the description of the present specification and the attached drawings.

Of the embodiments disclosed herein, typical ones are briefly outlined in the following.

In the semiconductor device manufacturing method according to an embodiment of the present invention, the locations of the opposing sides between the two photodiodes arranged side by side in each pixel are self-alignedly defined by a gate pattern, and the location over a wiring layer where a microlens is to be formed is checked and determined using as a reference a check pattern of a same layer as the gate layer.

The semiconductor device according to another embodiment of the present invention includes two photodiodes arranged in a pixel formed in a first area over a substrate, a gate pattern formed over the substrate between the two photodiodes, and a microlens formed in an upper part of the pixel. The semiconductor device further includes, in a second area over the substrate, a check pattern of the same layer as the gate pattern and a check pattern of the same layer as the microlens.

According to an embodiment of the invention disclosed in this specification, the performance of a semiconductor device can be improved. Particularly, the focusing accuracy of an image sensor can be improved.

### BRIEF DESCRIPTION OF THE DRAWINGS

FIG. 1 shows a flow of a semiconductor device manufacturing process according to a first embodiment of the present invention.

FIG. 2 is a sectional view for describing the semiconductor device manufacturing process according to the first embodiment of the present invention.

FIG. 3 is a plan view for describing the semiconductor device manufacturing process in continuation from FIG. 2.

FIG. 4 is a sectional view for describing the semiconductor device manufacturing process in continuation from FIG. 2.

FIG. 5 is a plan view for describing the semiconductor device manufacturing process in continuation from FIG. 3.

FIG. 6 is a sectional view for describing the semiconductor device manufacturing process in continuation from FIG. 4.

FIG. 7 is a plan view for describing the semiconductor device manufacturing process in continuation from FIG. 5.

FIG. 8 is a sectional view for describing the semiconductor device manufacturing process in continuation from FIG. 6.

FIG. 9 is a plan view for describing the semiconductor device manufacturing process in continuation from FIG. 7.

FIG. 10 is a plan view for describing the semiconductor device manufacturing process in continuation from FIG. 9.

FIG. 11 is a sectional view for describing the semiconductor device manufacturing process in continuation from FIG. 8.

FIG. 12 is a plan view for describing the semiconductor device manufacturing process in continuation from FIG. 10.

FIG. 13 is a sectional view for describing the semiconductor device manufacturing process in continuation from FIG. 11.

FIG. 14 is a plan view for describing the semiconductor device manufacturing process in continuation from FIG. 12.

FIG. 15 is a sectional view for describing the semiconductor device manufacturing process in continuation from FIG. 13.

FIG. 16 is a plan view for describing the semiconductor device manufacturing process in continuation from FIG. 14.

FIG. 17 is a sectional view for describing the semiconductor device manufacturing process in continuation from FIG. 15.

FIG. 18 is a schematic diagram showing the structure of a semiconductor device according to the first embodiment of the present invention.

FIG. 19 shows an equivalent circuit of a semiconductor device according to the first embodiment of the present invention.

FIG. 20 is a plan view of a semiconductor device according to the first embodiment of the present invention.

FIG. 21 is a plan view of a semiconductor device according to the first embodiment of the present invention.

FIG. 22 is a plan view of a semiconductor device according to the first embodiment of the present invention.

FIG. 23 is a plan view of a semiconductor device according to the first embodiment of the present invention.

FIG. 24 is a plan view of a semiconductor device according to the first embodiment of the present invention.

FIG. 25 is a plan view of a semiconductor device according to a second embodiment of the present invention.

FIG. 26 is a sectional view of the semiconductor device according to the second embodiment of the present invention.

FIG. 27 is a plan view for describing a semiconductor device manufacturing process according to a third embodiment of the present invention.

FIG. 28 is a plan view for describing the semiconductor device manufacturing process in continuation from FIG. 27.

FIG. 29 is a sectional view for describing the semiconductor device manufacturing process according to the third embodiment of the present invention.

FIG. 30 is a plan view for describing a semiconductor device manufacturing process according to a fourth embodiment of the present invention.

FIG. 31 is a sectional view for describing the semiconductor device manufacturing process according to the fourth embodiment of the present invention.

FIG. 32 is a plan view for describing the semiconductor device manufacturing process according to the fourth embodiment of the present invention.

FIG. 33 is a sectional view for describing the semiconductor device manufacturing process according to the fourth embodiment of the present invention.

FIG. 34 is a plan view for describing the semiconductor device manufacturing process according to the fourth embodiment of the present invention.

FIG. 35 is a plan view for describing the semiconductor device manufacturing process in continuation from FIG. 34.

FIG. 36 is a plan view for describing the semiconductor device manufacturing process in continuation from FIG. 35.

FIG. 37 is a sectional view for describing the semiconductor device manufacturing process according to the fourth embodiment of the present invention.

FIG. 38 is a plan view for describing a semiconductor device manufacturing process according to a fifth embodiment of the present invention.

FIG. 39 is a sectional view for describing the semiconductor device manufacturing process according to the fifth embodiment of the present invention.

FIG. 40 is a plan view for describing the semiconductor device manufacturing process in continuation from FIG. 38.

FIG. 41 is a plan view for describing the semiconductor device manufacturing process in continuation from FIG. 40.

FIG. 42 is a sectional view for describing the semiconductor device manufacturing process in continuation from FIG. 39.

FIG. 43 is a plan view for describing the semiconductor device manufacturing process in continuation from FIG. 41.

FIG. 44 is a sectional view for describing the semiconductor device manufacturing process in continuation from FIG. 42.

FIG. 45 is a plan view of an example semiconductor device for comparison.

FIG. 46 is a sectional view of an example semiconductor device for comparison.

### DETAILED DESCRIPTION

In the following, embodiments of the present invention will be described in detail with reference to drawings. Note that, in all drawings referred to in describing the following embodiments, parts and members having identical functions are denoted by identical reference numerals and symbols and that, as a rule, descriptions of such identical or similar parts and members are not repeated except when particularly necessary.

In the embodiments being described in the following, the well region of each pixel is formed in a P-type semiconductor region, and the photodiodes are formed in N-type semiconductor regions. However, the same effects can be obtained also in cases where the conductivity types of the well region and the photodiodes are different from the above-described. Also, in the embodiments being described in the following, the solid-state image sensor is of a type to which light is incident from above. However, as long as an identical device structure and an identical manufacturing process flow are used, the same effects can also be obtained using a solid-state image sensor of a back side illumination (BSI) type.

Also, in the following description, symbol “⁻” or “⁺” included in conductivity type indications represents a relative concentration of n-type or p-type impurities. For example, in the case of n-type impurities, the impurity concentration is higher in the order of “n⁻,” “n,” and “n⁺,” the “n⁺” being the highest. Also, the gate electrodes, gate patterns, and check patterns formed of semiconductor film of a same layer may collectively be referred to as a gate layer.

### First Embodiment

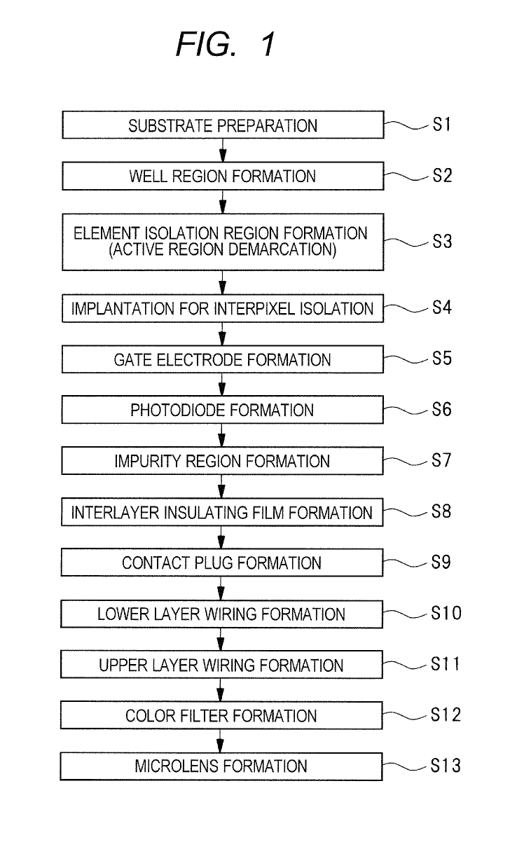

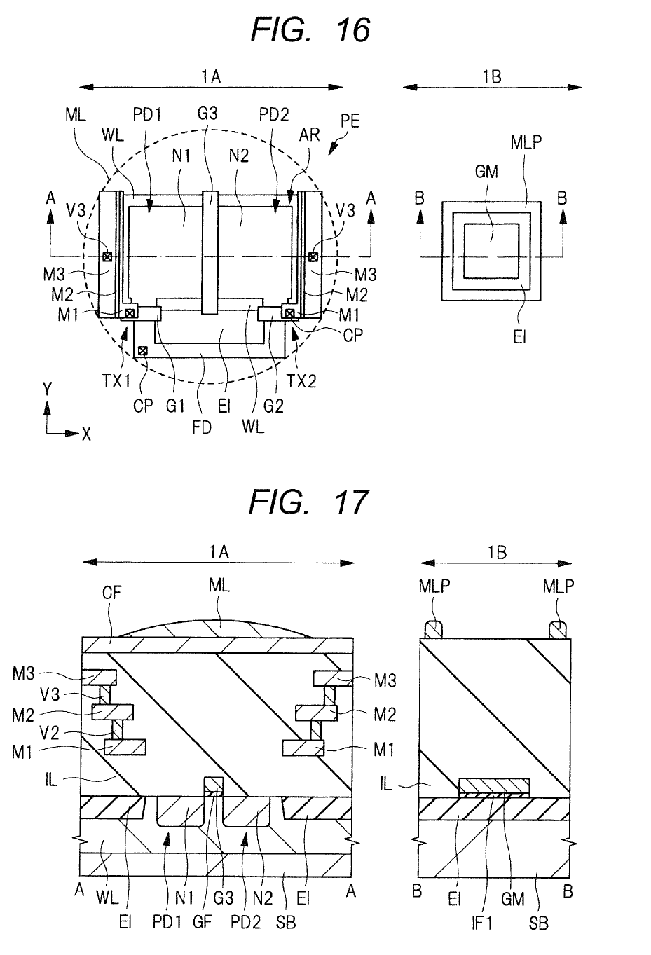

In the following, a semiconductor device manufacturing method and a semiconductor device according to a first embodiment of the present invention will be described with reference to FIGS. 1 to 17 and with reference to FIGS. 16 to 24, respectively. The semiconductor device of the present embodiment concerns a solid-sate image sensor, particularly, a solid-state image sensor having plural photodiodes within each pixel. The solid-state image sensor is a complementary metal oxide semiconductor (CMOS) image sensor and has a function to output information necessary for automatic focusing by a focus detection method based on image plane phase difference detection.

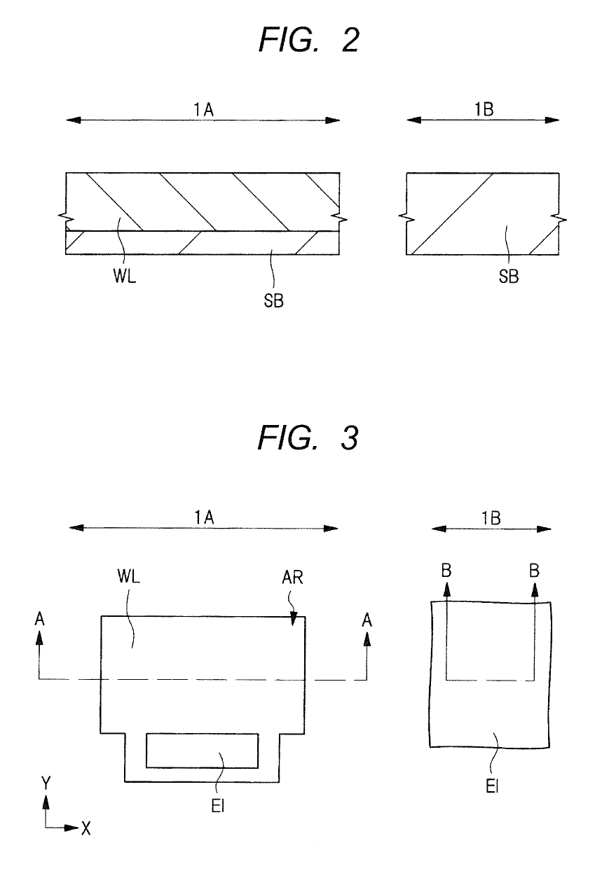

FIG. 1 shows a process flow of a semiconductor device manufacturing method according to the first embodiment of the present invention. FIGS. 2, 4, 6, 8, 11, 13, 15, and 17 are sectional views illustrating semiconductor device manufacturing processes according to the present embodiment. FIGS. 3, 5, 7, 9, 10, 12, 14, and 16 are plan views illustrating semiconductor device manufacturing processes according to the present embodiment. In each of the above sectional views and plan views, a pixel area 1A is represented on the left side and a check pattern area 1B is represented on the right side.

The following description is based on the assumption that each pixel included in the CMOS image sensor is a four-transistor pixel used as a pixel forming circuit in the CMOS image sensor, but an alternative type of pixel may also be used. In the plan views used for the following description, the above type of pixel is shown only with photodiodes and a floating diffusion capacitance part with some transistors, etc. omitted.

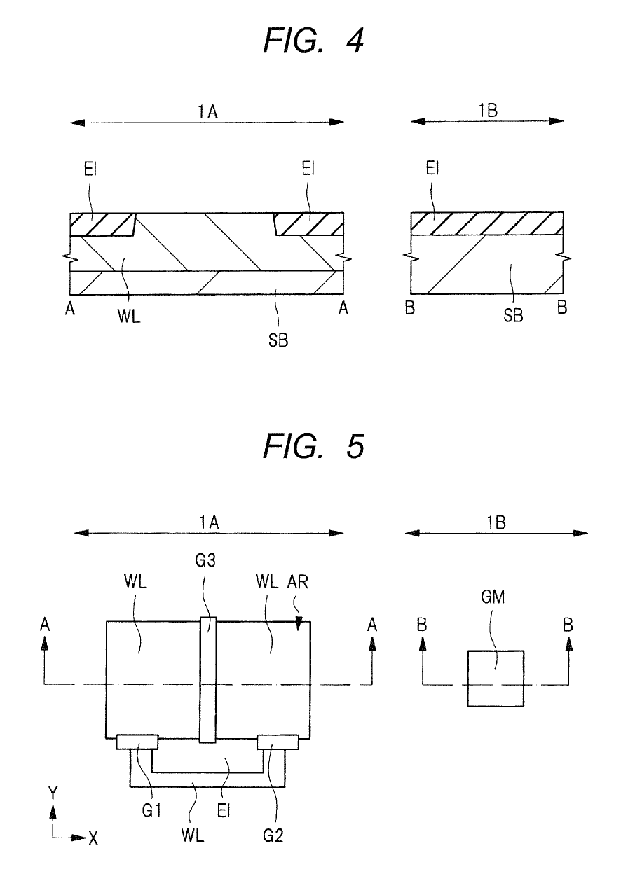

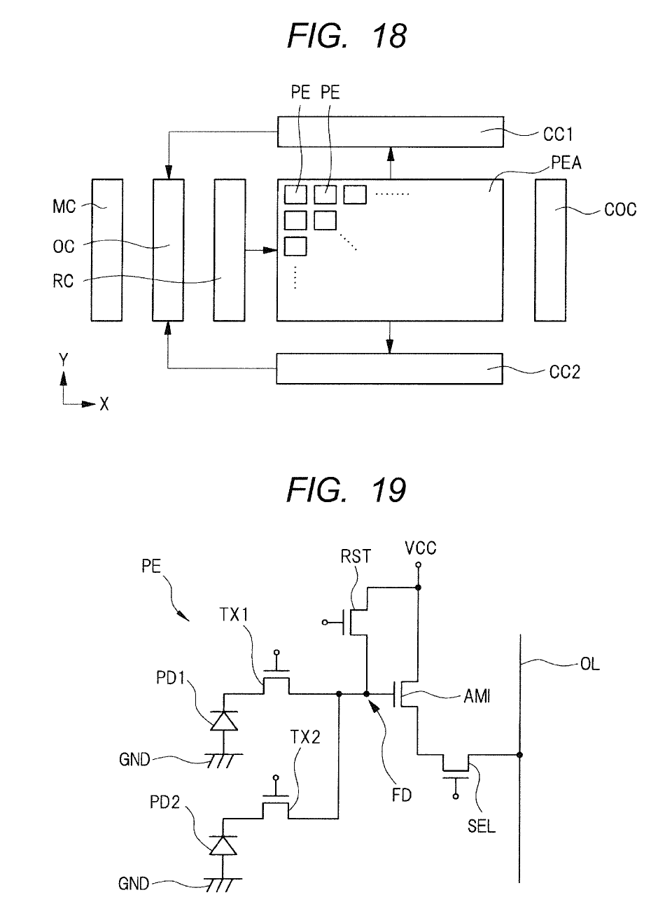

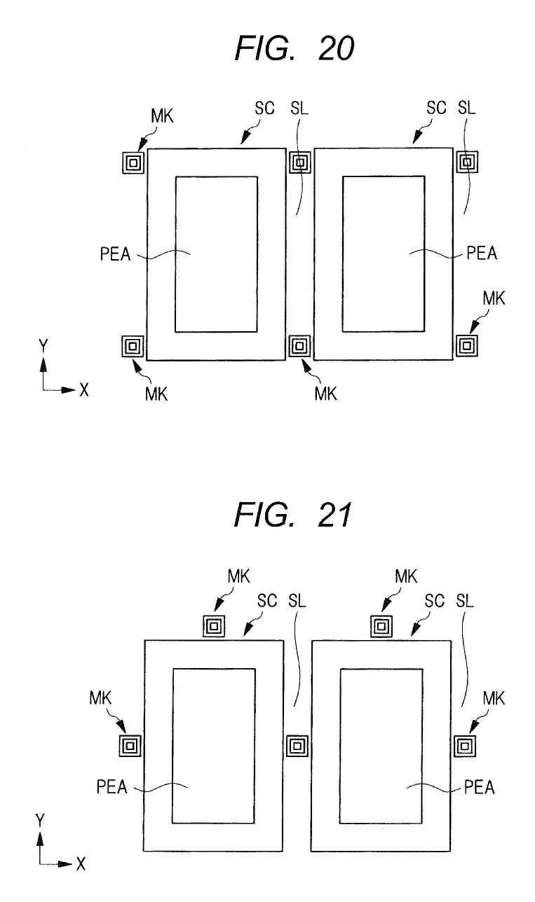

FIGS. 4, 6, 8, 11, 13, 15, and 17 show sectional views taken along lines A-A and B-B in FIGS. 3, 5, 7, 10, 12, 14, and 16, respectively. FIG. 18 is a schematic diagram showing the structure of the semiconductor device of the present embodiment. FIG. 19 shows an equivalent circuit of the semiconductor device of the present embodiment. FIGS. 20 to 24 are plan views showing locations where check patterns are formed in the semiconductor device of the present embodiment.

A pixel area 1A is an area where one of the pixels of an image sensor is formed. A check pattern area 1B is an area where superposition check patterns used to check/determine a location of microlens formation is formed. In the present embodiment, the check patterns are also used to check/determine, besides the microlens location, locations of forming semiconductor regions. The check pattern area 1B is located, as being described later with reference to FIGS. 20 to 24, inside a scribe line beside an area on a semiconductor substrate (semiconductor wafer) where a solid-state image sensor is formed or in an end portion of such an area where a solid-state image sensor is formed.

In the pixel area 1A, the active regions ARs of plural pixels are arranged to be laterally (in the X direction) adjoining. In this case, the active regions ARs are formed to be like a laterally extending belt and require, as being described later, interpixel isolation implantation to be performed to isolate each of the adjoining pixels. Pixel isolation is also possible by forming element isolation regions between the adjoining pixels instead of performing interpixel isolation implantation.

Referring to the manufacturing process flow shown in FIG. 1, first, a semiconductor substrate SB is prepared (step S1 in FIG. 1). Subsequently, a well region WL is formed over the semiconductor substrate SB (step S2 in FIG. 1). In the present embodiment, a well region WL is formed over the upper surface of the semiconductor substrate SB in the pixel area 1A, and no well region WL is formed over the upper surface of the semiconductor substrate SB in the pattern area 1B. However, a well region WL may also be formed over the upper surface of the semiconductor substrate in the check pattern area 1B.

The semiconductor substrate SB is formed of, for example, monocrystal silicon (Si). The well region WL is formed by introducing P-type impurities (e.g., boron (B)) into the main surface of the semiconductor substrate SB, for example, by an ion implantation method. The well region WL is a P⁻-type semiconductor region with a relatively low impurity concentration.

Next, as shown in FIGS. 3 and 4, trenches are formed on the main surface of the semiconductor substrate SB, and element isolation regions EI are formed in the trenches (step S3 in FIG. 1). This defines (demarcates) active regions, i.e. upper surface portions of the semiconductor substrate SB exposed in the element isolation regions EI. The element isolation regions EI can be formed, for example, by a shallow trench isolation (STI) method or by a local oxidization of silicon (LOCOS) method. In the present embodiment, the element isolation regions EI are formed by the STI method. In FIG. 3, an element isolation region EI in the check pattern area 1B is shown, but the element isolation region EI surrounding the active region AR is not shown. Similarly, in some of the plan views being referred to in the following description, the element isolation region EI in the check pattern area 1B is omitted. Referring to FIG. 3, the upper surface of the semiconductor substrate SB in the active region AR is entirely covered by the well region WL.

Being described in the following is a case in which each active region AR is formed after a well region WL is formed, but, alternatively, the active region AR may be formed before a well region WL is formed. In the alternatively case, it is necessary to perform P-type impurity implantation using an acceleration energy high enough to penetrate through the active region AR and the element isolation regions EI.

Also, in some of the plan views being referred to in the following description, interlayer insulating films are omitted and, depending on the case, wirings on the substrate are not shown, either. In FIGS. 2 to 17, the structure formed in the check pattern area 1B is represented smaller than the structure formed in the pixel area 1A. In reality, however, the structure formed in the check pattern area 1B is larger than a single pixel shown in the pixel area 1A.

Also, as shown in FIG. 3, the active region AR surrounded by the element isolation regions EI in the pixel area 1A includes an area to form, in a later process, a light receiving part including two photodiodes and an area to form a floating diffusion capacitance part which is a drain region of a transfer transistor used for charge accumulation. The area to form a light receiving part is rectangular as seen in a plan view. Both ends of the area to form a floating diffusion capacitance part are in contact with one of the four sides of the area to form the light receiving part. Namely, the active region AR has a rectangular ring structure including the above two areas, and an element isolation region EI is formed in a location surrounded by the two areas.

In other words, in the pixel area 1A shown in FIG. 3, the area to form the floating diffusion capacitance part is shaped such that the two portions thereof projecting, on the element isolation region EI side, from two parts of the one of the four sides of the area to form the light receiving part are coupled to each other. However, the two portions of the floating diffusion capacitance part projecting from the area to form the light receiving part need not necessarily be coupled to each other. When the two portions are not coupled to each other, the active region AR does not have a rectangular ring structure.

In the check pattern area 1B, an element isolation region EI is formed over the upper surface of the semiconductor substrate SB. As shown in FIG. 4, the element isolation regions EI have a depth not reaching the bottom of the well region WL.

Next, though not illustrated, impurity implantation for isolating the photodiodes being formed later, i.e. interpixel isolation implantation, is performed (step S4 in FIG. 1). Namely, in the pixel area 1A, a P-type semiconductor region, not shown, is formed over the upper surface of the semiconductor substrate SB by implanting P-type impurities (e.g., boron (B)), for example, by an ion implantation method, into an area surrounding the area for forming the photodiodes. The P-type semiconductor region is formed to be deeper than the N⁻-type semiconductor region where the photodiodes are to be formed later.

The interpixel isolation implantation is to form, between the pixels being formed later, potential barriers against electrons. This prevents electron diffusion between adjacent pixels and improves image sensor sensitivity characteristics.

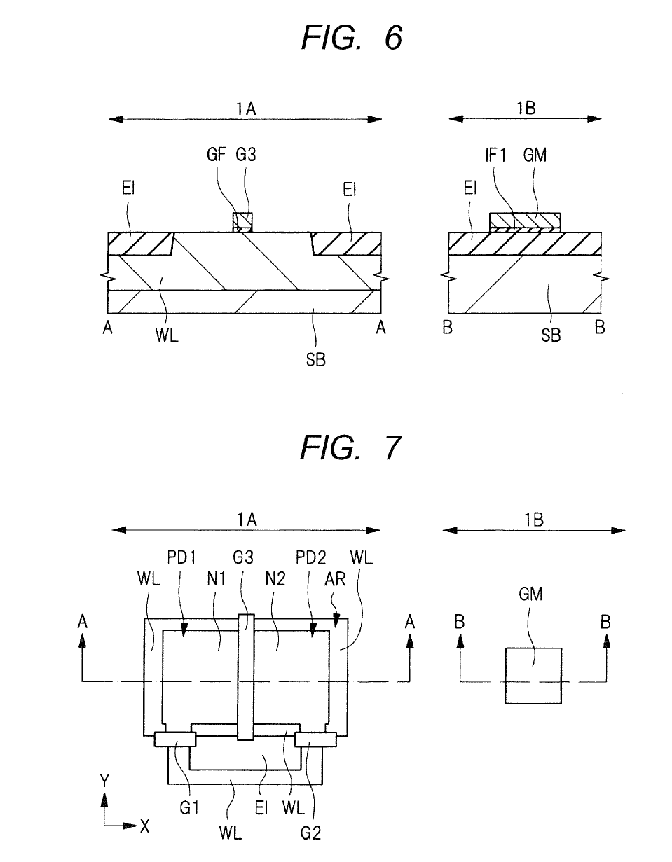

Next, as shown in FIGS. 5 and 6, gate electrodes are formed over the semiconductor substrate SB via a gate insulating film (step S5 in FIG. 1). Referring to FIG. 5, in the pixel area 1A, gate electrodes G1 and G2 are formed over, via a gate insulating film (not shown), boundary portions between the area to form the light receiving part and the area to form the floating diffusion capacitance part included in the active region AR. Namely, in the active region AR, the gate electrode G1 is formed right over one of the two portions of the floating diffusion capacitance part projecting from two parts of one side of the area to form the light receiving part, and the gate electrode G2 is formed right over the other of the two projecting portions. The gate electrodes G1 and G2 are to be the gate electrodes of transfer transistors to be formed later. In this step, the gate electrodes of peripheral transistors to be formed later are also formed in an area not shown.

In the process of forming the gate electrodes G1 and G2, a gate pattern (gate layer) G3 is also formed such that the gate pattern G3 divides the area to form the light receiving part in the active region AR included in the pixel area 1A into two at a center thereof as seen in a plan view. The gate pattern G3 is formed over the semiconductor substrate SB via an insulating film GF (see FIG. 6).

As seen in a plan view, the gate pattern G3 extends in the Y direction along the main surface of the semiconductor substrate. On both sides, in the X direction along the main surface of the semiconductor substrate that is perpendicular to the Y direction, of the gate pattern G3, the active region AR is exposed without being covered by the gate pattern G3. The area to form the light receiving part is divided into two by the gate pattern G3 as seen in a plan view. One of the projecting portions of the active region AR projects from one of the divided parts of the area to form the light receiving part, and the gate electrode G1 is formed right over the projecting portion. The other one of the projecting portions of the active region AR projects from the other one of the divided parts of the area to form the light receiving part, and the gate electrode G2 is formed right over the projecting portion.

In the process of forming the gate electrodes G1 and G2 and gate pattern G3, plural check patterns (gate layers) GM (only one is shown) are formed, via an insulating film IF1 (see FIG. 6), over the element isolation region EI in the check pattern area 1B. Each check pattern GM is, for example, rectangular as seen in a plan view. Note that, in FIG. 5, the element isolation region EI surrounding the check pattern GM is not shown.

In the present embodiment, after an insulating film and a semiconductor film are formed over the semiconductor substrate SB, the semiconductor film and the insulating film are processed using a photolithography technique and an etching method. In this way, using the insulating film, the foregoing gate insulating film and the insulating films GF and IF1 shown in FIG. 6 are formed, and, using the semiconductor film, the gate electrodes G1 and G2, gate pattern G3, and check patterns GM are formed.

Namely, the above gate insulating film and the insulating films GF and IF1 are of a same layer, that is, they are formed of films that were continuous when initially formed in a manufacturing process. The above gate insulating film and the insulating films GF and IF1 shown in FIG. 6 are formed of, for example, silicon oxide. When the above gate insulating film is formed, for example, by a thermal oxidation method, the insulating film IF1 need not be formed over the element isolation region EI in the check pattern area 1B.

The gate electrodes G1 and G2, the gate pattern G3, and the check pattern GM shown in FIG. 5 are of a same layer which is a gate layer of, for example, polysilicon film. The gate electrodes G1 and G2, the gate pattern G3, and the check pattern GM are patterns formed by processing performed using as a mask a photoresist film which was formed using a mask, so that they are formed to be spaced apart by predetermined distances. Namely, the location of the check pattern GM seldom varies relative to the gate pattern G3.

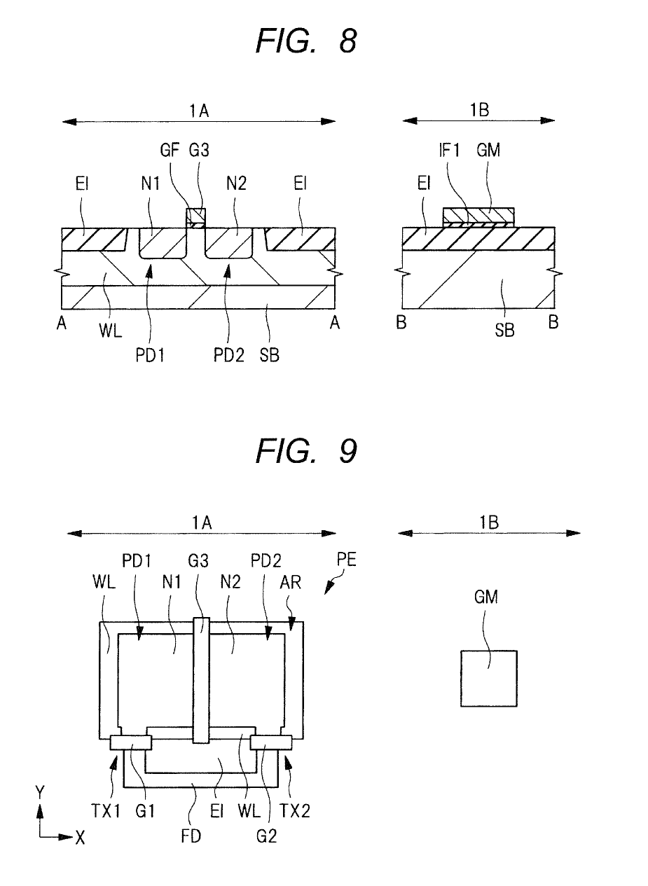

Next, referring to FIGS. 7 and 8, a photodiode PD1 including an N⁻-type semiconductor region N1 and a photodiode PD2 including an N⁻-type semiconductor region N2 are formed over the upper surface of the semiconductor substrate SB in the pixel area 1A (step S6 in FIG. 1). Namely, by implanting N-type impurities (e.g., arsenic (As) or phosphorus (P)) into the main surface of the semiconductor substrate SB in the pixel area 1A, for example, by an ion implantation method, N⁻-type semiconductor regions N1 and N2 are formed in the area to form a light receiving part included in the active region AR. The N⁻-type semiconductor regions N1 and N2 are formed on both sides, in the X direction, of the gate pattern G3, respectively, sandwiching the gate pattern G3 between them.

The impurity implantation by the ion implantation method is performed using a photoresist film (not shown) formed using a photolithography technique and the gate pattern G3 as masks. In this way, the N⁻-type semiconductor regions N1 and N2 are formed to be isolated from each other over the upper surface of the active region AR. The N⁻-type semiconductor regions N1 and N2 are approximately rectangular as seen in a plan view. The locations of the opposing sides between the N⁻-type semiconductor regions N1 and N2 are determined by the location where the gate pattern G3 is formed. Namely, the opposing portions to be isolated from each other of the N⁻-type semiconductor regions N1 and N2 are self-alignedly determined based on the gate pattern G3.

The side opposite to the side adjacent to the gate pattern G3 of each of the N⁻-type semiconductor regions N1 and N2 is spaced from the element isolation region EI surrounding the active region AR. A part of the N⁻-type semiconductor region N1 is formed in the semiconductor substrate SB portion in a region adjoining the gate electrode G1. A part of the N⁻-type semiconductor region N2 is formed in the semiconductor substrate SB portion in a region adjoining the gate electrode G2. Namely, the N⁻-type semiconductor region N1 is a field-effect transistor having the gate electrode G1 and makes up a source region of a transfer transistor TX1 to be formed in a later process. The N⁻-type semiconductor region N2 is a field-effect transistor having the gate electrode G2 and makes up a source region of a transfer transistor TX2 to be formed in a later process.

A portion of the main surface of the semiconductor substrate SB portion right below each of the gate electrodes G1 and G2 is a channel region where no N⁻-type semiconductor region is formed. As shown in FIG. 8, the N⁻-type semiconductor regions N1 and N2 are formed to be deeper than the element isolation region EI and shallower than the well region WL.

The location of the foregoing pattern formed of the photoresist film that determines the layout of the N⁻-type semiconductor regions N1 and N2 excluding their portions adjoining the gate pattern G3 is determined, as being described in the following, based on the check patterns GM.

To form a photoresist pattern to be used as an ion implantation mask in the process of forming the N⁻-type semiconductor regions N1 and N2, first, a photoresist film is applied over the semiconductor substrate SB and, subsequently, the photoresist film is exposed using an exposure mask (a photomask or a reticle) to transfer the exposure mask pattern to the photoresist film. When the photoresist film is subsequently processed for development, the photoresist pattern is formed.

When exposing the photoresist film, the check patterns GM are used to prevent exposure mask misalignment. For example, after forming a photoresist pattern, misalignment of the photoresist pattern is determined by measuring the distances in a plan view between the photoresist pattern and the check patterns GM. Subsequently, after once removing the photoresist pattern, the location of the exposure mask or the semiconductor substrate SB is appropriately shifted, then a photoresist pattern is formed again. In this way, a photoresist pattern not misaligned relative to the check patterns GM can be formed. Using the photoresist pattern thus formed as a mask makes it possible to form the N⁻-type semiconductor regions N1 and N2 without misalignment relative to the gate electrodes G1 and G2, the gate pattern G3, and the check patterns GM.

The gate electrodes G1 and G2, the gate pattern G3, and the check patterns GM are formed without misalignment relative to the layout of element isolation regions EI. This is done by checking their locations using superposition check patterns (not shown) formed in element isolation regions EI. The locations where the N⁻-type semiconductor regions N1 and N2 are formed may also be checked and determined using superposition check patterns (not shown) formed in element isolation regions EI. This can prevent the N⁻-type semiconductor regions N1 and N2 from being misaligned relative to the layout of the active region AR defined by element isolation regions ET.

As described above, the layout of the N⁻-type semiconductor regions N1 and N2 includes regions self-alignedly defined based on the gate pattern G3 and regions defined using the check patterns GM, so that the N⁻-type semiconductor regions N1 and N2 can be prevented from being misaligned relative to the respective gate patterns.

Forming the N⁻-type semiconductor regions N1 and N2 results in forming the photodiode PD1 that is a light receiving part including the N⁻-type semiconductor region N1 and a well region WL and the photodiode PD2 that is a light receiving part including the N⁻-type semiconductor region N2 and a well region WL. Namely, the well region WL forming a P-N junction with the N⁻-type semiconductor region N1 functions as an anode of the photodiode PD1, and the N⁻-type semiconductor region N1 functions as a cathode of the photodiode PD1. Also, the well region WL forming a P-N junction with the N⁻-type semiconductor region N2 functions as an anode of the photodiode PD2, and the N⁻-type semiconductor region N2 functions as a cathode of the photodiode PD2. In the active region AR, the N⁻-type semiconductor regions N1 and N2 are arranged side by side as seen in a plan view with the gate pattern G3 located between them.

Next, as shown in FIG. 9, a floating diffusion capacitance part FD, which is an N-type impurity region, is formed by implanting N-type impurities (e.g., arsenic (As) or phosphorus (P)) into a part of the active region AR, for example, by an ion implantation method (step S7 in FIG. 1). As a result, transfer transistors TX1 and TX2 are formed. The transfer transistor TX1 includes the floating diffusion capacitance part FD as a drain region, the N⁻-type semiconductor region N1 as a source region, and the gate electrode G1. The transfer transistor TX2 includes the floating diffusion capacitance part FD as a drain region, the N⁻-type semiconductor region N2 as a source region, and the gate electrode G2. In this process, peripheral transistors such as a reset transistor, an amplifier transistor, and a selection transistor are formed by forming a source/drain region in an area which is not shown.

The floating diffusion capacitance part FD is formed in the region projecting from the rectangular light receiving part in the active region AR. Namely, the active region AR is divided, as seen in a plan view, into the light receiving part including the photodiodes PD1 and PD2 and the floating diffusion capacitance part FD with the gate electrodes G1 and G2 located between them. The transfer transistors TX1 and TX2 share the floating diffusion capacitance part FD as a drain region. The transfer transistors TX1 and TX2 may be laid out to have separate drain regions, respectively. In such a case, their drain regions are electrically coupled to each other by a contact plug and wiring to be formed later.

Through the above processes, a pixel PE including the photodiodes PD1 and PD2, transfer transistors TX1 and TX2, and other peripheral transistors (not shown) is formed. Though not shown, plural pixels PE are arranged like a matrix in a pixel array part on the semiconductor substrate SB.

When forming an N-type photodiode, the above drain region is formed to have an N-type impurity concentration higher than that of the N⁻-type semiconductor regions N1 and N2. Even though there are cases in which photodiodes are formed by implanting P⁺ type impurities (e.g., boron (B)) into surface portions of photodiode regions like the N⁻-type semiconductor regions N1 and N2 shown in FIG. 8 to a depth smaller than that of the N⁻-type semiconductor regions N1 and N2 thereby forming shallow P⁺ layers, the following description is based on the assumption that there is not any P⁺ type surface layer.

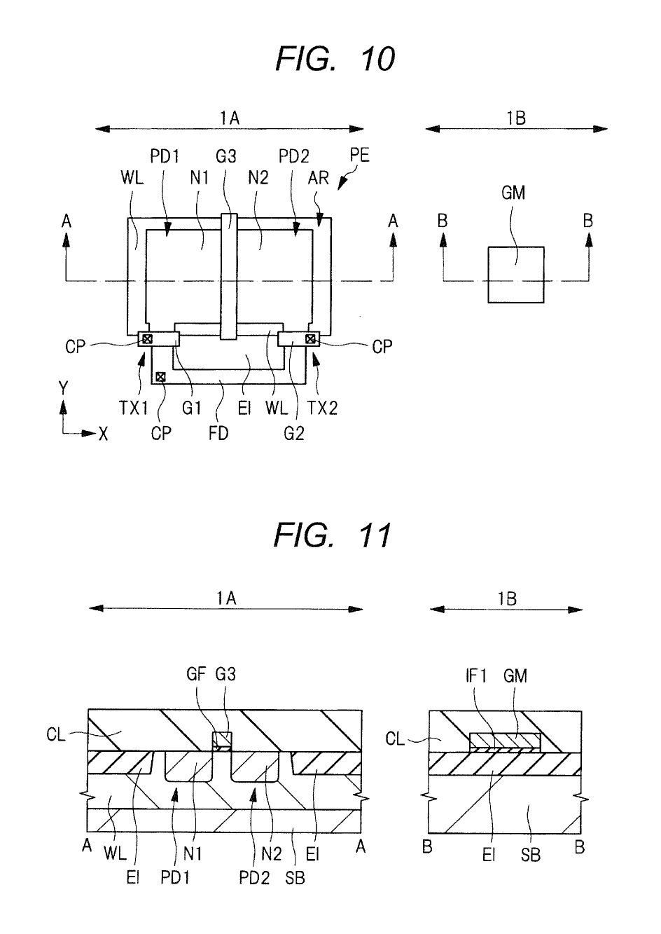

Next, as shown in FIGS. 10 and 11, an interlayer insulating film CL is formed over the semiconductor substrate (step S8 in FIG. 1) and, subsequently, contact plugs CP are formed through the interlayer insulating film CL (step S9 in FIG. 1).

An interlayer insulating film CL, for example, a silicon oxide film is formed over the main surface of the semiconductor substrate SB so as to cover the transfer transistors TX1 and TX2, the photodiodes PD1 and PD2, and the check patterns GM. This is done, for example, by a chemical vapor deposition (CVD) method. Subsequently, a photoresist pattern is formed over the interlayer insulating film CL, then, by performing dry etching using the photoresist pattern as a mask, contact holes to expose the gate electrodes G1 and G2 and the floating diffusion capacitance part FD are formed. The gate electrodes G1 and G2 and the floating diffusion capacitance part FD may have a silicide layer formed thereover. No contact hole is formed either right over the light receiving part including the photodiodes PD1 and PD2 or right over the check patterns GM.

Subsequently, a metal film is formed over the interlayer insulating film CL and the surfaces of the plural contact holes, then the metal film formed over the interlayer insulating film CL is removed by polishing, for example, by a chemical mechanical polishing (CMP) method. As a result, contact plugs CP formed of the metal film portions filling the contact holes are obtained. The metal film portion forming each of the contact plugs CP is a stacked film including, for example, a titanium nitride film covering the side wall and the bottom surface of the contact hole and a tungsten film deposited over the bottom surface of the contact hole via the titanium nitride film.

The locations of the contact plugs CP are determined by the locations of the contact holes. The locations of the contact holes to be formed using a photolithography technique are determined using as references the check patterns GM formed in the same layer as the gate electrodes G1 and G2. This prevents misalignment of the contact plugs CP relative to the gate electrodes G1 and G2. No contact plug CP is formed either right over the light receiving part including the photodiodes PD1 and PD2 or right over the check patterns GM.

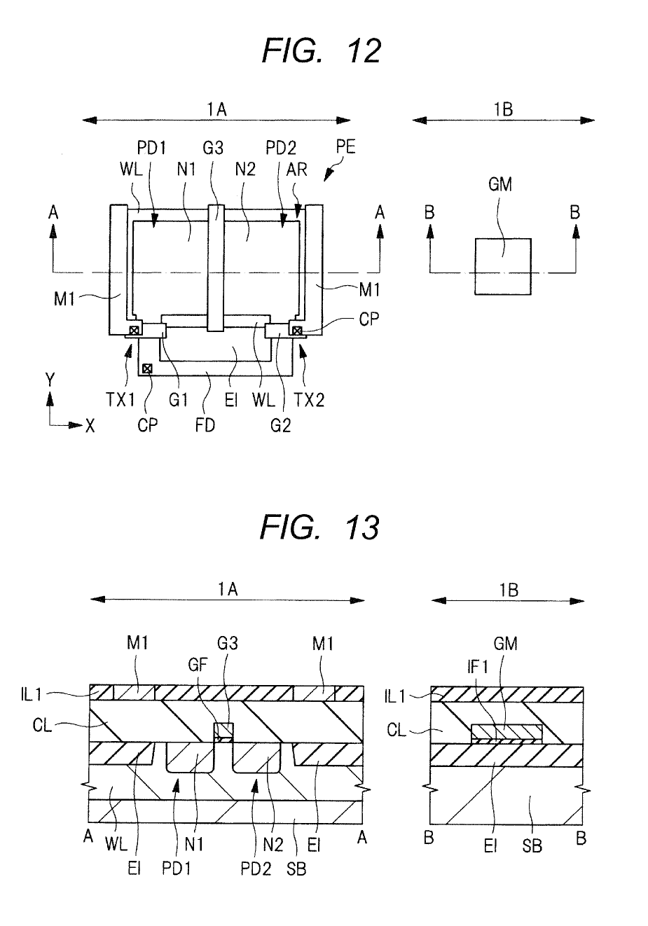

Next, as shown in FIGS. 12 and 13, a first wiring layer which includes an interlayer insulating film IL1 and lower-layer wirings M1 is formed over the interlayer insulating film CL (step S10 in FIG. 1). The lower-layer wirings are formed by a so-called single damascene method.

In the present embodiment, an interlayer insulating film IL1, for example, a silicon oxide film is formed over the interlayer insulating film CL, for example, by a CVD method. Subsequently, by processing the interlayer insulating film IL1 using a photolithography technique and a dry etching method, wiring trenches are formed through the interlayer insulating film IL1 as open portions to expose upper surfaces of the interlayer insulating film CL and contact plugs CP. Next, a metal film is formed over the interlayer insulating film IL1 including the surfaces of the wiring trenches, then the unrequired parts of the metal film over the interlayer insulating film IL1 are removed, for example, by a CMP method. As a result, wirings M1 are formed by the metal film buried in the wiring trenches. No wiring M1 is formed either right over the photodiodes PD1 and PD2 or right over the check patterns GM.

Each wiring M1 has a stacked structure in which tantalum nitride film and cupper film are sequentially stacked. The side walls and bottom surfaces of the wiring trenches are covered by a tantalum nitride film. The wirings M1 are, at the bottoms of the wiring trenches, coupled to the upper surfaces of the contact plugs CP. In FIG. 12, the wiring M1 coupled to the contact plug CP formed over the floating diffusion capacitance part FD is not shown. Also, in FIG. 12, the contact plug CP provided between each of the gate electrodes G1 and G2 and the corresponding wiring M1 is shown through the corresponding wiring M1 that is represented transparently.

The locations where the wirings M1 are formed are defined by the locations of the wiring trenches. The wiring trench locations are checked/determined based on the contact hole formation pattern.

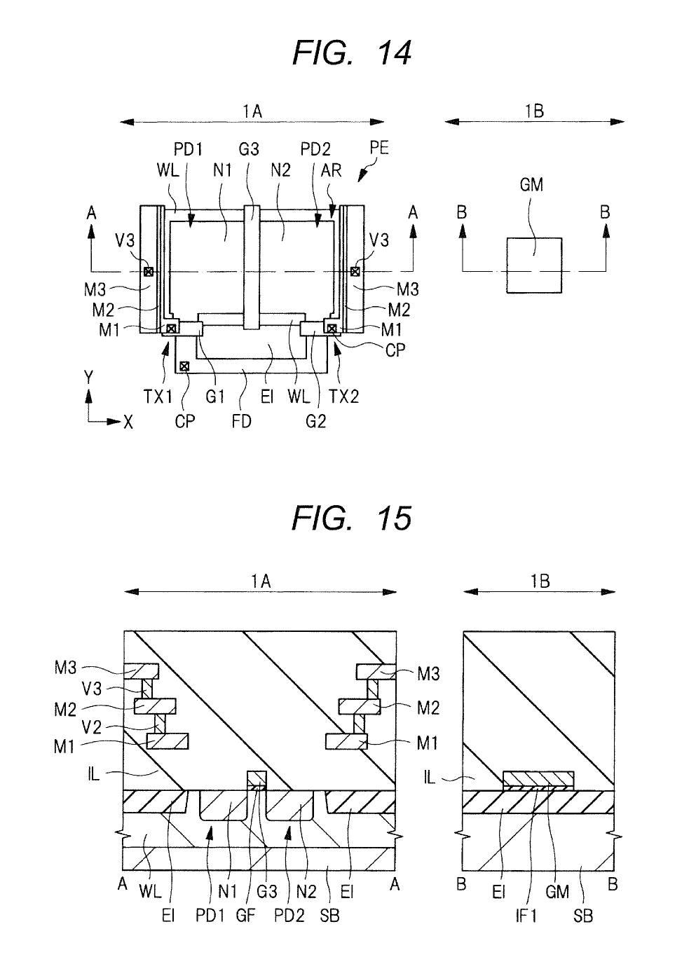

Next, as shown in FIGS. 14 and 15, plural wiring layers including plural upper layer wirings are stacked over the interlayer insulating film IL1 (see FIG. 13) (step S11 in FIG. 1). This forms a stacked wiring layer which includes the interlayer insulating film IL1, plural interlayer insulating films formed over the interlayer insulating film IL1, the wirings M1, and plural upper layer wirings stacked over the wirings M1. In the following, a structure which includes wirings M2 formed over the wirings M1 via via-hole plugs V2 and wirings M3 formed over the wirings M2 via via-hole plugs V3 will be described. Each upper layer wiring and the via-hole plug below each upper layer wiring are formed by a so-called dual damascene method. In FIG. 15, the interlayer insulating films CL and IL1 and the interlayer insulating film above them are represented as one interlayer insulating film IL.

The wirings M2 and M3 are formed more away from the photodiodes PD1 and PD2 than the wiring M1 as seen in a plan view. Namely, no wiring is formed right over the photodiodes PD1 and PD2. No wiring is formed right over the check patterns GM, either. Over each wiring M3 that is the highest-layer wiring in the stacked wiring layer, the interlayer insulating film IL is formed. In FIG. 14, via-hole plugs V3 formed between the wirings M3 and M2 are shown through the wirings M3 that are represented transparently.

In a dual damascene method, after a via-hole is formed through, for example, an interlayer insulating film, a wiring trench shallower than the via-hole is formed on the upper surface of the interlayer insulating film, then metal is buried in the via-hole and the wiring trench. In this way, the via-hole plug in the via-hole and the wiring in the wiring trench above the via-hole plug can be formed at the same time. Alternatively, a wiring trench may be formed first allowing a via-hole to be formed to extend from the bottom of the wiring trench to the bottom of the interlayer insulating film. The via-hole plugs V2 and V3 and the wirings M2 and M3 are mainly formed of cupper film. The wirings M1 are electrically coupled to the wirings M3 via the via-hole plugs V2, wirings M2, and via-hole plugs V3, respectively.

The wiring trenches and via-holes are formed by processing the interlayer insulating film using a photolithography technique and a dry etching method. When the wiring trenches are formed after the via-holes are formed as described above, the locations of the via-holes with the via-hole plugs V2 buried therein are checked/determined using the wiring M1 pattern as a reference. The locations where the wiring trenches with the wirings M2 buried therein are to be formed are checked/determined using as a reference the pattern of the via-holes in which the via-hole plugs V2 are to be buried. Similarly, the locations where the via-holes with the via-hole plugs V3 buried therein are to be formed are checked/determined using as a reference the pattern of the via-holes in which the via-hole plugs V3 are to be buried.

Next, as shown in FIGS. 16 and 17, in the pixel area 1A, a color filter CF is formed over the interlayer insulating film IL (step S12 in FIG. 1), then a microlens ML is formed over the color filter CF to be right over the pixel PE (step S13 in FIG. 1). In FIG. 16, the microlens ML is represented in broken line. The microlens ML and the photodiodes PD1 and PD2 are superposed as seen in a plan view.

Besides the photodiodes PD1 and PD2 and the floating diffusion region, each pixel PE also includes other transistors, but, for the sake of descriptive convenience, they are not shown in the attached drawings. In reality, such transistors are located to be superposed with the microlens ML as seen in a plan view.

The color filter CF is formed, for example, by burying a film which transmits light of a prescribed wavelength while blocking light of other wavelengths in a trench formed over the upper surface of the interlayer film IL1. In the present embodiment, no color filter CF is formed over the check patterns GM. To form the microlens ML over the color filter CF, a film formed over the color filter CF is processed into a circular pattern as seen in a plan view, then the film is rounded into a lens form, for example, by heating the film surface.

At the same time as the microlens ML is formed, check patterns MLP of the film of the same layer as the microlens ML are formed over the interlayer insulating film IL in the check area 1B. Each check pattern MLP conceivably has a rectangular ring structure with a planar layout thereof enclosing, as seen in a plan view, a check pattern GM. The following description assumes that each check pattern MLP is formed of a rectangular ring pattern including two sides extending in the Y direction and two sides extending in the X direction.

As seen in a plan view, each check pattern MLP is spaced apart from the check pattern GM enclosed therein. Referring to FIG. 16, for example, each side of the square check pattern GM measures 15 μm, and each side of the check pattern MLP measures 25 μm. Each portion extending in the Y or X direction of the check pattern MLP has a width in the X or Y direction of 2 to 4 μm. Namely, between the check pattern GM and the check pattern MLP surrounding the check pattern GM, there is a distance of 1 to 3 μm each on both sides of the check pattern GM in both the Y and X directions.

The microlens ML, on the other hand, has a diameter of, for example, 4 μm. Namely, even though the check patterns GM and MLP are shown relatively small in the figures, each superposition mark including a pair of check patterns GM and MLP is a pattern larger than a pixel.

A conceivable method of forming a pattern of the microlens ML is to process, using a photolithography technique or by an etching method, a transmissive film formed over the color filter CF. Namely, after a photoresist film is formed over the transmissive film using a photolithography technique, a photoresist pattern is formed by exposing and developing the photoresist film, and, subsequently, the transmissive film is processed using the photoresist pattern as a mask. When the transmissive film itself is light-sensitive, the patterns of the microlens ML and check patterns MLP can be formed of the transmissive film by exposing and developing the transmissive film.

The location where the microlens ML is formed is checked using the check patterns GM and MLP. Namely, to prevent misalignment of the microlens ML relative to the light receiving part of the pixel PE, the location of the exposure mask relative to the semiconductor substrate SB is adjusted using the check patterns GM and MLP.

The above adjustment is performed as follows. When forming the microlens ML using a photolithography technique as described above, first, a photoresist pattern is formed over the transmissive film. The photoresist pattern is formed, as seen in a plan view, in a circular area where the microlens ML is formed in the pixel area 1A. It is not formed outside the circular area. Photoresist patterns are also formed in areas where the check patterns MLP are formed in the check pattern area 1B. No photoresist pattern is formed either outside each rectangular ring area where a check pattern MLP is formed or in areas each surrounded by such a rectangular ring area.

The locational relationship between the photoresist pattern, i.e. the rectangular ring pattern, formed over the transmissive film to form a check pattern MLP and a check pattern GM is checked. If it is found that the rectangular ring pattern and the check pattern GM are not correctly aligned relative to each other, the amount of their misalignment is measured, then the photoresist pattern is removed. Subsequently, the photoresist pattern is formed again after the locations relative to each other of the exposure mask and the semiconductor substrate SB are adjusted based on the measured amount of misalignment. In this way, the photoresist pattern can be formed in a desired location. Using the photoresist pattern as a mask when forming the microlens ML and the check patterns MLP by etching can prevent misalignment of the microlens ML relative to the pixel PE.

Instead of checking the photoresist pattern and the check patterns GM for misalignment, an alternative method may be used in which: the transmissive film is processed using a photoresist pattern; the pattern of the microlens ML and each check pattern MLP are formed; and the check pattern MLP and the corresponding check pattern GM are checked for misalignment. If the check pattern MLP is found to have been formed in a misaligned location, the microlens ML and the check pattern MLP are once removed and, after the location of the check pattern MLP is corrected taking into account the amount of the misalignment, the microlens ML and the check pattern MLP are formed again.

When directly processing the light-sensitive transmissive film by exposure and development without forming the photoresist pattern, after the microlens ML and the check patterns MLP are formed, the location of the microlens ML is checked for misalignment using the check patterns GM and MLP. If, as a result, the check patterns MLP are found out of desired locations, the microlens ML and the check patterns MLP are once removed, then they are formed again after the locations where they are to be formed are corrected.

In the present embodiment, the location of the microlens ML is checked/determined using the check patterns GM formed of the film of the same layer as the gate electrodes G1 and G2 and the gate pattern G3. As described above, after forming a pattern of a specific film, a photoresist pattern for forming the specific pattern, or a mask pattern for ion implantation, the locations where such patterns are formed can be checked using the check patterns GM. The check patterns GM can also be used as marks, i.e. alignment marks, for determining the location of an exposure mask prior to exposure operation.

The principal features of the present embodiment include self-alignedly forming, based on the gate pattern G3, an area where the N⁻-type semiconductor regions N1 and N2 are separated from each other and preventing misalignment between the N⁻-type semiconductor regions N1 and N2 and the microlens ML by defining the location of the microlens ML using as references the check patterns GM of the same layer as the respective gate electrodes.

In the ensuing process, the semiconductor substrate SB, i.e. the semiconductor wafer, is diced along the scribe lines into plural discrete sensor chips, thereby forming plural solid-state image sensors formed of the sensor chips. In this way, the semiconductor device including the solid-state image sensor according to the present embodiment is completed.

In the following, the structure and operation of the solid-state image sensor according to the present embodiment will be described with reference to FIGS. 16 to 19. The semiconductor device according to the present embodiment is a CMOS image sensor and includes, as shown in FIG. 18, a pixel array part PEA, readout circuits CC1 and CC2, an output circuit OC, a row selection circuit RC, a control circuit COC, and a memory circuit MC.

In the pixel array part PEA, plural pixels PE are arranged like a matrix. Namely, over the upper surface of the semiconductor substrate included in the solid-state image sensor, the pixels PE are arranged along the X-axis direction and the Y-axis direction. Each pixel PE is surrounded by an element isolation region (pixel isolation structure). Referring to FIG. 18, the X-axis direction is a direction along the main surface of the semiconductor substrate included in the solid-state image sensor and extends along the rows of pixels PE. The Y-axis direction perpendicular to the X-axis direction is also a direction along the main surface of the semiconductor substrate and extends along the columns of pixels PE.

Each pixel PE generates a signal corresponding to the intensity of light received. The row selection circuit RC selects plural pixels PE on a row-by-row basis. The pixels PE selected by the row selection circuit RC output the signals generated by them to an output line OL (see FIG. 19) being described later. The readout circuits CC1 and CC2 are located to oppose each other in the Y-axis direction across the pixel array part PEA. The readout circuits CC1 and CC2 each read out signals outputted from pixels PE to the output line OL and output the signals they read out to the output circuit OC. The memory circuit MC is a storage part for temporarily storing the signals outputted from the output line OL.

The readout circuit CC1 reads out the signals generated by one half, on the readout circuit CC1 side, of the pixels PE arranged in the pixel array part, and the readout circuit CC2 reads out the signals generated by the other half, on the readout circuit CC2 side, of the pixels PE arranged in the pixel array part. The output circuit OC outputs the signals of the pixels PE read out by the readout circuits CC1 and CC2 to outside the solid-state image sensor. The control circuit COC manages the operation of the solid-state image sensor on an overall basis, and controls operations of other components of the solid-state image sensor. The memory circuit MC is used to measure the magnitudes of charges outputted from the two photodiodes of each pixel PE by memorizing the signal outputted from one of the two photodiodes.

FIG. 19 shows a pixel circuit. Each of the pixels PE shown in FIG. 18 has a circuit shown in FIG. 19. As shown in FIG. 19, each pixel PE includes photodiodes PD1 and PD2 to perform photoelectric conversion, a transfer transistor TX1 to transfer the charge generated in the photodiode PD1, and a transfer transistor TX2 to transfer the charge generated in the photodiode PD2. The pixel PE also includes a floating diffusion capacitance part FD to accumulate the charge transferred from the transfer transistors TX1 and TX2 and an amplifier transistor AMI to amplify the potential of the floating diffusion capacitance part FD. The pixel PE further includes a selection transistor SEL to determine whether or not to output the potential amplified at the amplifier transistor AMI to the output line OL coupled to one of the readout circuits CC1 and CC2 (see FIG. 18) and a reset transistor RST to reset the potentials of the cathodes of the photodiodes PD1 and PD2 and the floating diffusion capacitance part FD to predetermined potentials. The transfer transistors TX1 and TX2, reset transistor RST, amplifier transistor AMI, and selection transistor SEL are, for example, N-type MOS transistors.

The anodes of the photodiodes PD1 and PD2 are each applied with a ground potential GND that is a negative-side power supply potential. The cathodes of the photodiodes PD1 and PD2 are coupled to the sources of the transfer transistors TX1 and TX2, respectively. The floating diffusion capacitance part FD is coupled to the drains of the transfer transistors TX1 and TX2, the source of the reset transistor RST, and the gate of the amplifier transistor AMI. The drains of the reset transistor RST and amplifier transistor AMI are each applied with a positive-side power supply potential VCC. The source of the amplifier transistor AMI is coupled to the drain of the selection transistor SEL. The source of the selection transistor SEL is coupled to the output line OL coupled to one of the readout circuits CC1 and CC2.

Next, operation of the pixel will be described. First, the gate electrodes of the transfer transistors TX1 and TX2 and the reset transistors RST are each applied with a prescribed potential, putting the transfer transistors TX1 and TX2 and the reset transistor RST into an on-state. This causes the residual charges in the photodiodes PD1 and PD2 and the accumulated charge in the floating diffusion capacitance part FD to flow toward the positive-side power supply potential VCC to, thereby, initialize the charges in the photodiodes PD1 and PD2 and in the floating diffusion capacitance part FD. Subsequently, the reset transistor RST enters an off-state.

Next, when the P-N junction of each of the photodiodes PD1 and PD2 is irradiated with incident light, photoelectric conversion occurs at each of the photodiodes PD1 and PD2. As a result, charge is generated in each of the photodiodes PD1 and PD2. The charge thus generated is entirely transferred to the floating diffusion capacitance part FD by the transfer transistors TX1 and TX2. The charge transferred to the floating diffusion capacitance part FD is accumulated there, causing the potential of the floating diffusion capacitance part FD to vary.

Next, when the selection transistor SEL enters an on-state, the potential after variation of the floating diffusion capacitance part FD is amplified by the amplifier transistor AMI and is subsequently outputted to the output line OL. Subsequently, the readout circuit CC1 or CC2 reads out the potential from the output line OL. In cases where automatic focusing is performed based on image plane phase difference detection, the charges in the photodiodes PD1 and PD2 are not simultaneously transferred to the floating diffusion capacitance part FD by the transfer transistor TX1 and TX2, respectively. In that case, the charges are sequentially transferred and read out. In imaging operation, the charges in the photodiodes PD1 and PD2 are simultaneously transferred to the floating diffusion capacitance part FD.

In the following, operation of the solid-state image sensor of the present embodiment will be described in more detail mainly referring to FIG. 19. The operation of the solid-state image sensor includes imaging and automatic focusing.

First, pixel operation for imaging will be described. For imaging, the gate electrodes of the transfer transistors TX1 and TX2 and the reset transistor RST are applied with a prescribed potential and are, thereby, put in an on-state. This causes the residual charges in the photodiodes PD1 and PD2 and the accumulated charge in the floating diffusion capacitance part FD to flow toward the positive-side power supply potential VCC to, thereby, initialize the charges in the photodiodes PD1 and PD2 and in the floating diffusion capacitance part RD. Subsequently, the reset transistor RST enters an off-state.

Next, when the P-N junction of each of the photodiodes PD1 and PD2 is irradiated with incident light, photoelectric conversion occurs at each of the photodiodes PD1 and PD2. As a result, charge L1 is generated in the photodiode PD1 and charge R1 is generated in the photodiode PD2. Namely, the photodiodes PD1 and PD2 are light receiving elements, which internally generate signal charges by photoelectric conversion corresponding to the quantities of incident light, i.e., photoelectric conversion elements.

Next, the charges L1 and R1 are transferred to the floating diffusion capacitance part FD. In imaging operation, the two photodiodes PD1 and PD2 included in the pixel PE are operated as a single photoelectric conversion part, so that the charges in the photodiodes PD1 and PD2 are read out after being combined into one signal. Namely, in the imaging operation, the charge signals generated in the two photodiodes PD1 and PD2 are collected, after being added, as a single piece of pixel information.

Therefore, it is not necessary to read out the charges in the photodiodes PD1 and PD2 separately. The charges in the photodiodes PD1 and PD2 are transferred to the floating diffusion capacitance part FG by turning the transfer transistors TX1 and TX2 on. This causes the charges transferred from the photodiodes PD1 and PD2 to be accumulated in the floating diffusion capacitance part FD, causing the potential of the floating diffusion capacitance part FD to vary.

In the above process, the charges are combined as follows. First, with the charge L1 accumulated in the photodiode PD1 and the charge R1 accumulated in the photodiode PD2, the transfer transistors TX1 and TX2 are turned on by applying a voltage to the gate electrodes G1 and G2 of the transfer transistors TX1 and TX2. This causes the charges L1 and R1 to be transferred to the floating diffusion capacitance part FD to be combined there.

Next, the selection transistor SEL is put in an on-state, and the potential after variation of the floating diffusion capacitance part FD is amplified by the amplifier transistor AMI. This outputs an electrical signal corresponding to the potential variation of the floating diffusion capacitance part FD to the output line OL. Namely, by making the selection transistor SEL operate, the electrical signal outputted by the amplifier transistor AMI is outputted to outside. As a result, the readout circuit CC1 or CC2 (see FIG. 18) reads out the potential of the output line OL.

Next, pixel operation for automatic focusing performed based on image plane phase difference detection will be described. In the solid-state image sensor that is the semiconductor device of the present embodiment, each pixel includes plural photoelectric conversion parts (e.g. photodiodes). When the solid-state image sensor is applied to, for example, a digital camera having an automatic focus detection system using an image plane phase difference detection method, the plural photodiodes included in each pixel improve the accuracy and speed of automatic focusing.

In such a digital camera, the distance by which the lens of the digital camera is to be moved for focusing is calculated based on the difference, i.e. phase difference, between the signal detected by one of the photodiodes included in each pixel and the signal detected by the other of the photodiodes included in each pixel. This enables quick automatic focusing. Including plural photodiodes in each pixel results in forming an increased number of fine photodiodes in a solid-state image sensor, so that automatic focusing accuracy is improved. Therefore, for automatic focusing operation unlike for the above-described imaging operation, it is necessary to read out the charges generated in the plural photodiodes included in each pixel separately.

In the automatic focus detection operation, first, a prescribed potential is applied to the gate electrode of each of the transfer transistors TX1 and TX2 and the reset transistor RST, thereby putting the transfer transistors TX1 and TX2 and the reset transistor RST in an on-state. This initializes the charge in each of the photodiodes PD1 and PD2 and the floating diffusion capacitance part FD. Subsequently, the reset transistor RST is put in an off-state.

Next, the P-N junction of each of the photodiodes PD1 and PD2 is irradiated with incident light, causing photoelectric conversion to occur at each of the photodiodes PD1 and PD2. As a result, charge is generated in each of the photodiodes PD1 and PD2. In the following, the charge generated in the photodiode PD1 will be referred to as charge L1, and the charge generated in the photodiode PD2 will be referred to as charge R1.

Next, one of the charges is transferred to the floating diffusion capacitance part FD. In the present example, first, by turning the transfer transistor TX1 on, the charge L1 in the photodiode PD1 is read out to the floating diffusion capacitance part FD, thereby varying the potential of the floating diffusion capacitance part FD. Subsequently, the selection transistor SEL is put in an on-state, and the potential after variation of the floating diffusion capacitance part FD is amplified by the amplifier transistor AMI. The amplified potential is then outputted to the output line OL. Namely, an electrical signal corresponding to the potential variation in the floating diffusion capacitance part FD, i.e. a charge detection part, is outputted after being amplified by the amplifier transistor AMI. The potential of the output line OL is read out by the readout circuit CC1 or CC2 (see FIG. 18). The signal representing the charge L1 read out from the output line OL is stored in the memory circuit MC (see FIG. 18).

At this time, the charge L1 generated in the photodiode PD1 is still left in the floating diffusion capacitance part FD, and the potential of the floating diffusion capacitance part FD is in a state of having been varied. Also, the charge R1 in the photodiode PD2 is still left without being transferred.

Next, the transfer transistor TX2 is turned on, and the charge R1 in the photodiode PD2 is read out to the floating diffusion capacitance part FD. This further varies the potential of the floating diffusion capacitance part FD.

As a result, in the floating diffusion capacitance part FD, the charge L1 transferred from the photodiode PD1 and stored in the floating diffusion capacitance part FD and the charge R1 transferred, after the charge L1, from the photodiode PD2 are combined and stored in the floating diffusion capacitance part FD. Namely, the charge L1+R1 is stored in the floating diffusion capacitance part FD.

Subsequently, the selection transistor SEL is put in an on-state, and the potential after variation of the floating diffusion capacitance part FD is amplified by the amplifier transistor AMI. The amplified potential is outputted to the output line OL to be then read out by the readout circuit CC1 or CC2 (see FIG. 18). To calculate the charge R1 generated in the photodiode PD2 from the value of charge L1+R1 read out as described above, the value of the charge L1 stored in the memory circuit MC (see FIG. 18) is subtracted from the value of charge L1+R1. In this way, the charge R1 generated in the photodiode PD2 can be read out. This calculation is performed, for example, in the control circuit COC (see FIG. 18).

Next, for automatic focus detection, the distance by which the lens of the digital camera is to be moved for focusing is calculated based on the difference, i.e. phase difference, between the charges L1 and R1 detected from the photodiodes PD1 and PD2 included in each pixel PE arranged in the pixel array part PEA (see FIG. 18).

When, as described above, reading out the charges in the photodiodes PD1 and PD2 sequentially, the charge R1 in the photodiode PD2 may be read out first to be followed by the charge L1 in the photodiode PD1.

There is also an alternative method conceivable for automatic focusing in which the operation to calculate the charge R1 from the value of combined charge L1+R1 is omitted. In the method, after the transfer transistor TX1 is turned on first and the charge L1 is read out and stored, the floating diffusion capacitance part FD is reset by turning on the reset transistor RST. This makes it possible to subsequently read out the charge R1 in the photodiode PD2 alone by turning on the transfer transistor TX2. In this case, too, it is necessary to store the charge L1 in the memory circuit MC (see FIG. 18), but the charges L1 and R1 can be read out separately without performing the foregoing calculation.

When a digital camera including the solid-state image sensor of the present embodiment is used whether to shoot a still image or video, the foregoing imaging operation is performed in each pixel. During video shooting, the above-described automatic focusing operation is performed in each pixel. For still image shooting, there are cases in which the above-described automatic focusing operation is performed in each pixel and other cases in which the above-described automatic focusing operation is not performed in each pixel and, instead, an automatic focusing device not included in the solid-state image sensor is used.

Next, with reference to FIGS. 16 and 17, the structure of a semiconductor device of the present embodiment will be described. As shown in FIG. 16, the area of a pixel PE in a pixel area 1A is mostly occupied by a light receiving part where the photodiodes PD1 and PD2 are formed. Plural peripheral transistors (not shown) are located around the light receiving part. The light receiving part and the active region of each peripheral transistor are surrounded by element isolation regions EI. The peripheral transistors mentioned herein refer to the reset transistor RST, amplifier transistor AMI, and selection transistor SEL shown in FIG. 19.

The active region AR of the light receiving part shown in FIG. 16 is approximately rectangular as seen in a plan view. In the active region AR, the photodiodes PD1 and PD2 are arranged side by side in the X-axis direction. The photodiodes PD1 and PD2 are spaced from each other, and they are each rectangular as seen in a plan view. A gate pattern G3 is formed right over the semiconductor substrate portion between the photodiodes PD1 and PD2.

A floating diffusion capacitance part FD is a semiconductor region which is formed in the active region AR and functions as a drain region of the transfer transistors TX1 and TX2. The floating diffusion capacitance part FD is in an electrically floating state, so that the charge accumulated therein is retained unless the reset transistor is operated.

The drain region of the transfer transistors TX1 and TX2 is an N⁺-type semiconductor region formed over the main surface of the semiconductor substrate. The upper surface of the semiconductor region is coupled with a contact plug CP. The upper surface of each of the gate electrodes G1 and G2 is also coupled with a contact plug CP.

The photodiode PD1 includes an N⁻-type semiconductor region N1 formed over the main surface of the semiconductor substrate and a well region WL which is a P-type semiconductor region. Similarly, the photodiode PD2 includes an N⁻-type semiconductor region N2 formed over the main surface of the semiconductor substrate and a well region WL. The photodiodes PD1 and PD2 that are light receiving elements can be regarded as being formed in the N⁻-type semiconductor regions N1 and N2, respectively. In the active region AR, the N⁻-type semiconductor regions N1 and N2 are respectively surrounded by P⁻-type well regions WL.

The active region AR is approximately rectangular as seen in a plan view. One of the four sides of the approximate rectangle has two projecting parts extending to be coupled with each other. Namely, the active region AR has a rectangular ring shape as seen in a plan view and includes the projecting parts and the rectangular light receiving part. As seen in a plan view, an element isolation region EI is formed inside the rectangular ring shape. The projecting parts make up the drain regions of the transfer transistors TX1 and TX2. Namely, the transfer transistors TX1 and TX2 share the floating diffusion capacitance part FD as their drain regions. The gate electrodes G1 and G2 are located to stride over the two projecting parts, respectively.

When outputting a captured image, the signals (charges) in the two photodiodes of each pixel are combined and outputted as one signal. This makes it possible to obtain an image of quality equivalent to that of a solid-state image sensor with each pixel including only one photodiode.

A stacked wiring layer including wirings M1, M2, and M3 is formed over the semiconductor substrate. As seen in a plan view, the wirings are not superposed with the light receiving part including the photodiodes PD1 and PD2.

Referring to FIG. 16, in the check pattern area 1B, an element isolation region EI is formed over the semiconductor substrate. Over the element isolation region EI, a check pattern GM is formed of the film of the same layer as the gate electrodes G1 and G2 and the gate pattern G3. A check pattern MLP of the film of the same layer as the microlens ML is formed over the interlayer insulating film (not shown) formed over the check pattern GM. The check pattern MLP has a rectangular ring shape surrounding the check pattern area 1B as seen in a plan view. The check pattern GM is formed of the film of the same layer as the gate electrodes G1 and G2 and the gate pattern G3 and equals them in height. The microlens ML and the check pattern MLP are of the same layer and are equal in height to each other.

In FIG. 17, a pixel PE (see FIG. 16) in the pixel area 1A is shown in a sectional view taken along the direction in which the photodiodes PD1 and PD2 are arranged in the pixel PE. In the sectional views shown in FIG. 17, the layer boundaries between plural interlayer insulating films layered over the semiconductor substrate SB are not shown. As shown in the pixel area 1A shown in FIG. 17, a P⁻-type well region WL is formed over the upper surface of the semiconductor substrate SB formed of an N-type monocrystal silicon. Over the well region WL, element isolation regions EI are formed for demarcating the active region from other active regions. The element isolation regions EI are each formed of a silicon oxide film and are each buried in a trench formed in the upper surface of the semiconductor substrate SB.

N⁻-type semiconductor regions N1 and N2 are formed spaced apart from each other in the upper surface of the N⁻-type well region WL. The well region WL forming a P-N junction with the N⁻-type semiconductor region N1 functions as an anode of the photodiode PD1. The well region WL forming a P-N junction with the N⁻-type semiconductor region N2 functions as an anode of the photodiode PD2. The N⁻-type semiconductor regions N1 and N2 are formed in an active region between element isolation regions EI. A gate pattern G3 is formed over the semiconductor substrate SB portion between the N⁻-type semiconductor regions N1 and N2 via an insulating film GF.

As described above, in the active region formed in the pixel, the photodiode PD1 including the N⁻-type semiconductor region N1 and the well region WL and the photodiode PD2 including the N⁻-type semiconductor region N2 and the well region WL are formed. In the active region, the photodiodes PD1 and PD2 are arranged side by side with the well region WL exposed over the upper surface of the semiconductor substrate SB portion between them.

The N⁻-type semiconductor regions N1 and N2 are formed to be deeper than the well region WL. The trenches with element isolation regions EI buried therein in the upper surface of the semiconductor substrate SB are shallower than the N⁻-type semiconductor regions N1 and N2.

An interlayer insulating film IL is formed over the semiconductor substrate SB covering the element isolation regions EI and the photodiodes PD1 and PD2. The interlayer insulating film IL is a stacked layer including plural stacked insulating films. In the interlayer insulating film IL, plural wiring layers are stacked. In the lowest wiring layer, wirings M1 are formed which are covered by the interlayer insulating film IL. Wirings M2 are formed over the wirings M1 via the interlayer insulating film IL. Wirings M3 are formed over the wirings M2 via the interlayer insulating film IL. A color filter CF is formed over the interlayer insulating film IL. The microlens ML is formed over the color filter CF. During operation of the solid-state image sensor, the photodiodes PD1 and PD2 are irradiated with light via the microlens ML and the color filter CF.

No wiring is formed right over the active region where the photodiodes PD1 and PD2 are formed. This is to prevent any wiring from blocking the light incident through the microlens ML to reach the photodiodes PD1 and PD2 making up the light receiving part of the pixel. With the wirings M1 to M3 located outside the active region, the occurrence of photoelectric conversion outside the active region where the peripheral transistors, etc. are formed is prevented.

In the check pattern area 1B shown in FIG. 17, an element isolation region EI is formed in a trench formed in the upper surface of the semiconductor substrate SB, and the check pattern GM is formed over the element isolation region EI via an insulating film IF1. The interlayer insulating film IL is formed over the check pattern GM covering the top surface and side walls of the check pattern GM. The check pattern MLP is formed over the interlayer insulating film IL.

The check pattern MLP is formed right over a region adjoining the check pattern GM, that is, the check pattern MLP is not formed right over the check pattern GM. No wiring is formed right over the check pattern GM, either. This allows, when the microlens ML is formed using the check pattern GM as a superposition mark, the check pattern GM to be viewed from above the interlayer insulating film IL without being disturbed by any wiring.

Next, with reference to FIGS. 20 to 24, the locations where check patterns for use as superposition marks are formed will be described. In FIGS. 20 to 23, the check patterns GM and MLP shown in FIG. 16 are both represented as superposition marks MK. FIGS. 20 to 23 are plan views each showing two of the sensor chip areas SC arranged over a semiconductor wafer. Namely, FIGS. 20 to 23 are plan views each showing a portion of a semiconductor wafer before being divided by dicing.

FIGS. 20 to 23 are for describing the locations where superposition marks MK are formed based on different examples. Any one of the layouts of superposition marks MK shown in FIGS. 20 to 23 may be adopted. An alternative layout not shown in FIGS. 20 to 23 may also be adopted. In FIGS. 20 to 23, plural superposition marks MK are located outside the pixel array parts.

When a semiconductor wafer is divided by dicing, each sensor chip area SC makes up a sensor chip. The sensor chip areas SC arranged along the Y direction and the X direction over the surface of a semiconductor wafer are spaced apart from one another by scribe lines (scribe areas, dicing areas) SL. The scribe areas are cut by dicing blades when a semiconductor wafer is divided by dicing.

As shown in FIG. 20, each sensor chip area SC includes a pixel array part PEA in a central part thereof. In the pixel array part PEA, plural pixels PE (see FIG. 18) are arranged like a matrix. The area surrounding the pixel array part PEA in each sensor chip area SC, i.e. an outer marginal area of each sensor chip area SC, is where such circuits as readout circuits, an output circuit, a row selection circuit, a control circuit, and a memory circuit and also wire bonding pads are formed.

Each sensor chip area SC is rectangular as seen in a plan view and is surrounded by scribe lines SL. Namely, the sensor chip areas SC adjacent to one another are separated by scribe lines SL. In the example shown in FIG. 20, superposition marks MK are formed over scribe lines SL. In the example shown in FIG. 20, superposition marks MK are located, as seen in a plan view, beside the four corners of each sensor chip area SC to be adjacent to one another in the X direction. Superposition marks MK may also be located, as shown in FIG. 21, in center portions of the scribe lines SL adjoining the four sides of each sensor chip area SC, respectively.

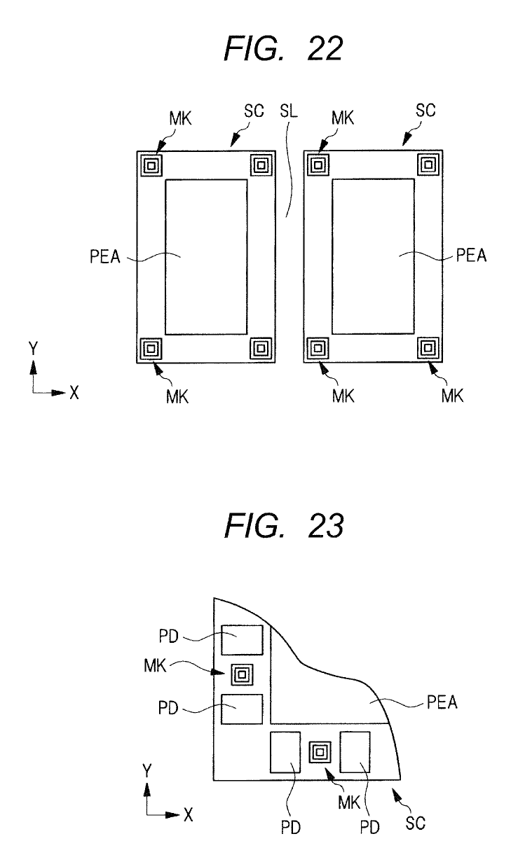

Also, as shown in FIG. 22, superposition marks MK may be formed in the sensor chip areas SC. In the example shown in FIG. 22, superposition marks MK are located in each sensor chip area SC to be beside the inner corners of the sensor chip area SC and to be outside the pixel array part PEA. With dicing technology improving and scribe lines SL growing smaller in width, there may be cases in which it is difficult to locate superposition marks MK over scribe lines SL. It is conceivable that, in such cases, superposition marks MK are formed inside each sensor chip area SC. There may also be cases in which, with many types of test elemental groups (TEGs) located over scribe lines SL, superposition marks MK cannot be located over scribe lines SL. In such cases, too, superposition marks MK are conceivably located in each sensor chip area SC.

Also, as shown in FIG. 23, in each sensor chip area SC, superposition marks MK may be located not beside the inner corners of the sensor chip area SC but between plural pads PD which are located in a marginal portion along the four sides of the sensor chip area SC. FIG. 23 is an enlarged plan view of a portion around a corner of a sensor chip area SC.

When superposition marks MK are located inside each sensor chip area SC as described above, the superposition marks MK in each sensor chip area SC are retained even after the semiconductor wafer is diced into individual sensor chips.

Even with superposition marks MK located over scribe lines SL outside each sensor chip area SC as shown in FIGS. 20 and 21, there are cases in which, after the semiconductor wafer is diced into individual sensor chips, superposition marks MK remain, either partly or wholly, in marginal portions of individual sensor chip areas SC. This is considered to occur when scribe lines SL are cut using thin dicing blades, causing significant portions of scribe lines SL to be left as marginal portions of individual sensor chip areas SC.

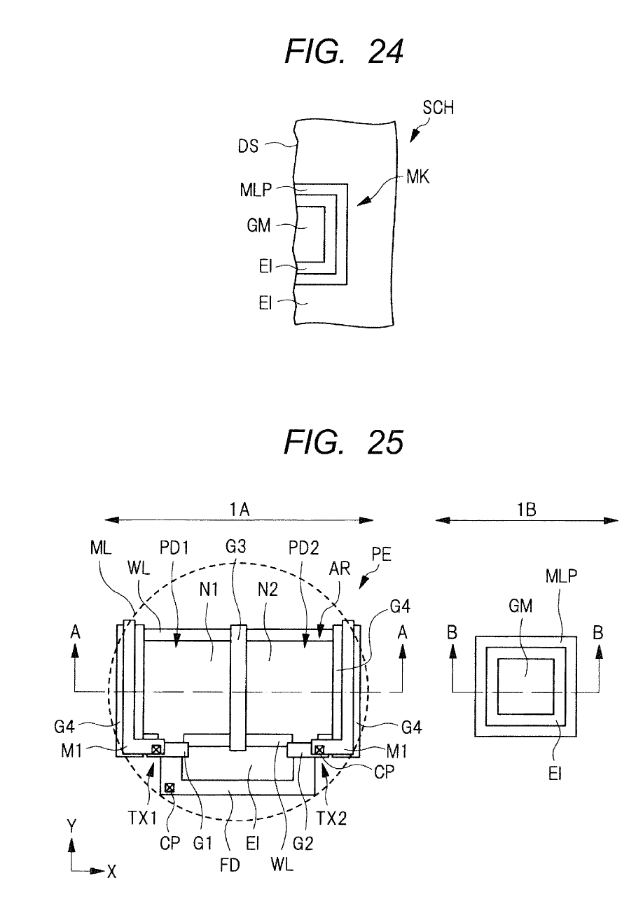

FIG. 24 shows an example case in which the check patterns GM and MLP making up a superposition mark MK are partly left without being wholly cut off by dicing. FIG. 24 is an enlarged plan view of a scribe line portion left in a marginal portion of a sensor chip SCH. In FIG. 24, “DS” denotes a diced surface, generated by wafer dicing, of a sensor chip SCH. In the following description, scribe line portions left without being cut off from each sensor chip SCH are regarded as parts of the sensor chip SCH. Namely, the diced surface makes up a side of the sensor chip SCH.

Referring to the plan view of FIG. 24, the check patterns GM and MLP are located in contact with the diced surface DS and, within the sensor chip, the check pattern MLP is formed to surround the check pattern GM. An element isolation region EI is formed between the check patterns GM and MLP and also outside the check pattern MLP. Like in this example, even when superposition marks MK are formed over scribe lines, there are cases in which the superposition marks MK are left, either partly or wholly, without being cut off by wafer dicing.

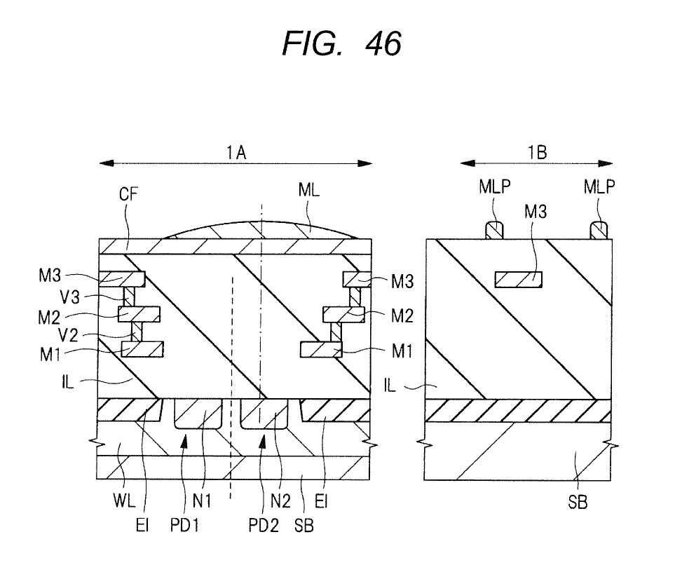

In the following, effects of the semiconductor device of the present embodiment will be described with reference to FIGS. 45 and 46 showing examples for comparison. FIG. 45 is a plan view of an example semiconductor device for comparison. FIG. 46 is a sectional view of an example semiconductor device for comparison. FIG. 45 shows a pixel area 1A and a check pattern area 1B like in FIG. 16. FIG. 46 shows a pixel area 1A and a check pattern area 1B like in FIG. 17. In the example shown by the sectional view of FIG. 46, the microlens is misaligned relative to the pixel.

The semiconductor devices shown as examples for comparison in FIGS. 45 and 46 are structured identically to the semiconductor device of the present embodiment described with reference to FIGS. 2 to 17 except for the following aspects. Namely, the example semiconductor devices for comparison have no gate pattern G3 (see FIG. 16) right over the semiconductor substrate SB portion between the N⁻-type semiconductor regions N1 and N2. Also, in the example semiconductor devices for comparison, the check pattern formed in the check pattern area 1B includes a wiring M3 and a check pattern MLP of the same layer as the microlens ML. In the example semiconductor device shown in FIG. 45, the check pattern MLP is formed to surround the check pattern formed of the wiring M3 in the check pattern area 1B.

Namely, the N⁻-type semiconductor regions N1 and N2 are not self-alignedly formed using a pattern of the same layer as the gate electrodes G1 and G2 as a mask. Furthermore, the microlenses ML included in the example semiconductor devices for comparison are formed using the highest-layer wirings M3 as references among the wirings layered over the semiconductor substrate SB. The above aspects of the example semiconductor devices for comparison make the example semiconductor devices different from the semiconductor device of the present embodiment.

In the process of manufacturing the example semiconductor devices for comparison, impurities for forming the N⁻-type semiconductor regions N1 and N2 are implanted by lithography using element isolation regions EI as references. Also, the microlens ML used to irradiate the photodiodes PD1 and PD2 with light is formed by lithography using the highest-layer wirings M3 as references. The highest-layer wirings M3 are formed by lithography using, as references, marks which are holes formed thereunder in the process of forming via-holes in which via-hole plugs V3 are buried. The via-holes are formed using, as references, metal-film marks formed thereunder in the process of forming the wirings M2.

The lowest-layer wirings M1 are formed using, as references, marks which are contact holes formed thereunder and in which contact plugs CP are buried. The contact holes are formed using, as references, patterns of the same layer as the gate electrodes G1 and G2. The gate electrodes G1 and G2 are formed using, as references, element isolation regions EI.

As described above, whereas the locations of the N⁻-type semiconductor regions N1 and N2 are determined using the element isolation regions EI as references, the microlens ML is formed by lithography after superposition alignment is indirectly repeated for plural layers following initial alignment based on the element isolation regions EI. Hence, significant misalignment tends to occur between the N⁻-type semiconductor regions N1 and N2 and the microlens ML. In FIG. 46, a chain line extends through the center of the microlens ML and a broken line extends through the center between the N⁻-type semiconductor regions N1 and N2, both the chain line and the broken line extending perpendicularly to the main surface of the semiconductor substrate SB. It is desirable that the chain line and the broken line coincide, but, in FIG. 46, they are shifted from each other indicating that the N⁻-type semiconductor regions N1 and N2 and the microlens ML are not correctly aligned.

When an object is imaged with focusing achieved based on image plane phase difference detection, the light incident through an exit pupil (camera lens) should uniformly reach the photodiodes PD1 and PD2 included in the solid-state image sensor causing the photodiodes PD1 and PD2 to produce equal incident light outputs. In the case of the example semiconductor device for comparison shown in FIG. 46 in which the N⁻-type semiconductor regions N1 and N2 and the microlens ML are not correctly aligned relative to each other, however, the incident light outputs from the photodiodes PD1 and PD2 may not match even in a focused state. In such a case, even with focusing achieved, the camera lens is moved by a distance corresponding to the magnitude of misalignment between the N⁻-type semiconductor regions N1 and N2 and the microlens ML. This consequently produces a defocused image.

According to the present embodiment, by forming, as shown in FIGS. 16 and 17, a gate pattern G3 between the photodiodes PD1 and PD2 included in a same active region AR of a pixel PE, the N⁻-type semiconductor regions N1 and N2 are self-alignedly formed to be separate from each other. Also, according to the present embodiment, check patterns GM are formed as superposition marks of the same layer as the gate pattern G3 and, without forming any wiring pattern right over the check patterns GM, the check patterns GM are used as a reference layer for forming the microlens ML.

The end portions on the gate pattern G3 side of the N⁻-type semiconductor regions N1 and N2 that are self-alignedly formed by ion implantation are not misaligned relative to the gate pattern G3. Also, forming the microlens ML using the check patterns MLP based on the check patterns GM as references minimizes misalignment between the center of the microlens ML and the center between the N⁻-type semiconductor regions N1 and N2. This is because the microlens ML and the N⁻-type semiconductor regions N1 and N2 are all formed using the gate pattern G3 as a reference.

Thus, in automatic focusing by the use of a solid-state image sensor (sensor chip), focusing accuracy can be improved. This eventually improves performance of the semiconductor device.

In cases where it is not possible to form the microlens ML by lithography directly using the check patterns GM as references because of an effect of the color filter CF located right under the microlens ML, the highest-layer wirings M3 may be formed by lithography using the check patterns GM as references to be then followed by lithography to form the microlens ML using the wirings M3 as references.

In this case compared with cases where, as in the case of the example semiconductor devices for comparison, a microlens is formed involving a total alignment error resulting from plural alignment operations indirectly performed for the element isolation region through the highest-layer wirings, the magnitude of misalignment between the microlens ML and the N⁻-type semiconductor regions N1 and N2 can be greatly reduced. Thus, in automatic focusing by the use of a solid-state image sensor (sensor chip), focusing accuracy can be improved. This eventually improves performance of the semiconductor device.

In the layouts shown in FIGS. 20 to 23, superposition marks MK are located outside the effective pixel areas (pixel array parts PEAs) as seen in a plan view. Namely, superposition marks MK are located to surround each pixel array part PEA in which the N⁻-type semiconductor regions N1 and N2 and the microlens ML are required to be accurately aligned in each pixel. Therefore, when the superposition marks MK beside the four corners of each pixel array part PEA are located as prescribed by a relevant superposition standard, the magnitude of misalignment between the microlens and the gate layer in each pixel arranged in each pixel array part PEA which is surrounded by the superposition marks MK located beside the four corners thereof can be easily kept within the misalignment of the super position marks MK located beside the four corners of each pixel array part PEA.

Also, referring to FIGS. 16 and 17, the potential of the gate pattern G3 need not be varied. Its potential is preferably fixed or kept floating. For example, when it is desired to fix the potential of the gate pattern G3 at ground potential, it is not necessary to have a potential supply line additionally extended from a control circuit region outside the image area (pixel array part) because a ground potential region is already included in each pixel PE. This can reduce the number of wirings in the pixel area 1A, so that optical vignetting caused by optical shields is reduced to improve sensitivity characteristics.

Though, when the gate pattern G3 is to be kept at a negative potential, a negative potential supply line is required, dark electrons generated in an interface state near the gate pattern G3 can be recombined with holes generated at a negative potential, so that noise in dark-time imaging can be reduced. Also, when the gate patter G3 is put in a floating state, the gate wirings or metal wirings for coupling to the gate pattern G3 can be reduced, so that optical vignetting can be reduced to improve sensitivity characteristics

Since the gate wirings or metal wirings for coupling to the gate pattern G3 need not be formed, the coupling capacitance generated between the control signal lines for the transfer transistors TX1 and TX2 used to transfer the charges in the photodiodes PD1 and PD2 to the floating diffusion capacitance part FD and other wirings can be reduced. This makes it possible to reduce the capacitance of the control signal wirings for the gate electrodes G1 and G2, to reduce the charge/discharge current related with the capacitance, and to eventually reduce the power consumption by the semiconductor device.

In the present embodiment, each photodiode uses a P-type well region as an anode and a diffusion layer which is an N⁻-type semiconductor region as a cathode, but effects similar to those obtained in the present embodiment can also be obtained using a solid-state image sensor including an alternative type of photodiodes, for example, photodiodes each including an N-type well and a P⁻-type diffusion layer included in the N-type well or photodiodes each including a diffusion layer of the same conductivity type as the pixel well formed on the surface thereof. Also, the present embodiment has been described based on the assumption that the wirings in the wiring layer are made of cupper (Cu), but the wirings are not limited to cupper. For example, the wirings formed mainly of aluminum (Al) or tungsten (W) may be used.

### Second Embodiment

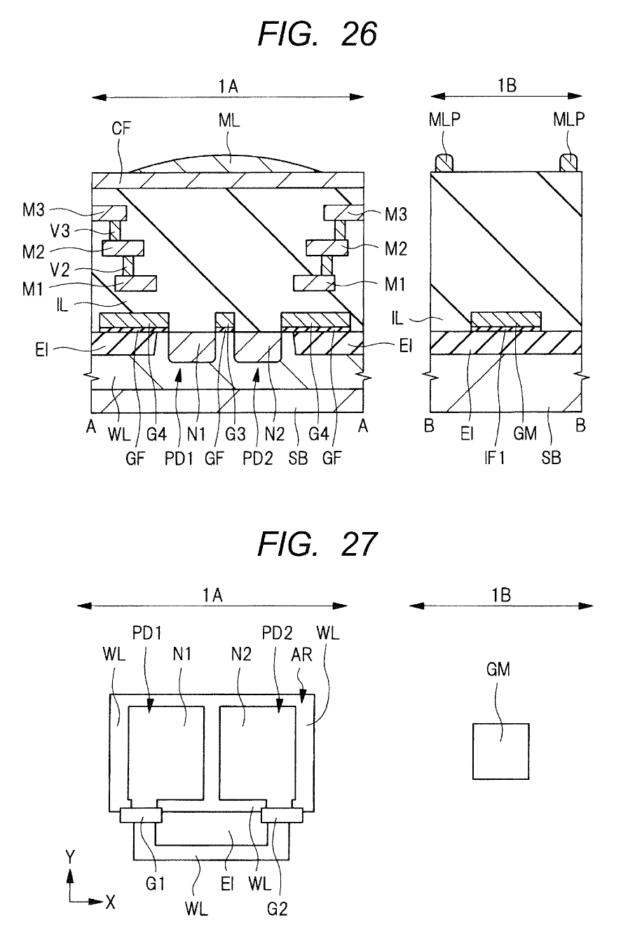

In a second embodiment of the present invention compared with the foregoing first embodiment, more portions of each photodiode are self-alignedly formed using a gate pattern. FIG. 25 is a plan view of a semiconductor device according to the second embodiment. FIG. 26 shows sectional views taken along lines A-A and B-B in FIG. 25. In each of FIGS. 25 and 26 like in FIGS. 16 and 17, a pixel area 1A and a check pattern area 1B are shown. In FIG. 25 showing a finished pixel PE, the wirings other than wirings M1 and the via-hole plugs are omitted to make the drawing easier to understand.

The present embodiment as shown in FIGS. 25 and 26 differs from the first embodiment in that a pair of gate patterns (gate layer) G4 are formed on both sides, in the X direction, of a gate pattern G3. The gate patterns G4 are of the same layer as gate electrodes G1 and G2, gate pattern G3, and check patterns GM that are formed over the semiconductor substrate SB via an insulating film GF.

Namely, the gate patterns G4 are formed in the process in which the gate electrodes G1 and G2, gate pattern G3, and check patterns GM are also formed. The main feature associated with the aspects of the present embodiment differing from the first embodiment is that the N⁻-type semiconductor regions N1 and N2 are self-alignedly formed using both of the gate patterns G3 and G4. Namely, in the present embodiment, of the four sides of each of the N⁻-type semiconductor regions N1 and N2, not only the side on the pixel PE center side in the X direction but also the side away from the pixel PE center in the X direction has its location self-alignedly defined using a gate layer as a reference.

Problems likely to occur if the gate patterns G4 are not formed are as follows. When a gate layer is used as a reference in performing lithography to form a resist pattern to be used as a mask for ion implantation in the ion implantation process (step S6 in FIG. 1) described with reference to FIGS. 7 and 8, a lateral superposition error, i.e. a superposition error in the X direction, may occur between the gate layer and the resist pattern. When such a superposition error occurs, the two areas into which impurity ions are implanted to form the N⁻-type semiconductor regions N1 and N2 on both sides of the gate pattern G3 become unequal. This eventually makes the N⁻-type semiconductor regions N1 and N2 unequal in area. In such a state, even when focusing is perfectly performed, the outputs from the photodiodes PD1 and PD2 become unequal.

According to the present embodiment, on the other hand, in the gate layer formation process (step S5 in FIG. 1) described with reference to FIGS. 5 and 6, in addition to the gate pattern G3 formed between the photodiodes PD1 and PD2, a pair of gate patterns G4 are formed to extend in the Y direction on both sides, in the X direction, of the gate pattern G3 and the photodiodes PD1 and PD2. This allows, out of the two sides in the X direction of each of the N⁻-type semiconductor regions N1 and N2, one to be self-alignedly formed by ion implantation using the gate pattern G3 as a mask and the other to be self-alignedly formed by ion implantation using one of the pair of gate patterns G4 as a mask.

Namely, the locations of the two sides extending in the Y direction of each of the rectangular N⁻-type semiconductor regions N1 and N2 are self-alignedly defined. Therefore, even if a lateral superposition error occurs as a result of performing lithography using a gate layer as a reference in the ion implantation process for forming the N⁻-type semiconductor regions N1 and N2, the photodiodes PD1 and PD2 can be prevented from becoming unequal in area to each other. Thus, even when the above superposition error occurs, the relative locational relationship between the gate layer and the photodiodes PD1 and PD2 does not change. This makes it possible to increase the production margin susceptible to superposition errors and to improve the reliability of the semiconductor device.

According to the present embodiment, the effects similar to those obtained in the first embodiment can be obtained.

Like the gate pattern G3, the gate patterns G4 do not require their potentials to be particularly varied. Preferably, they are fixed at a negative potential or ground potential or left in a floating state.

### Third Embodiment

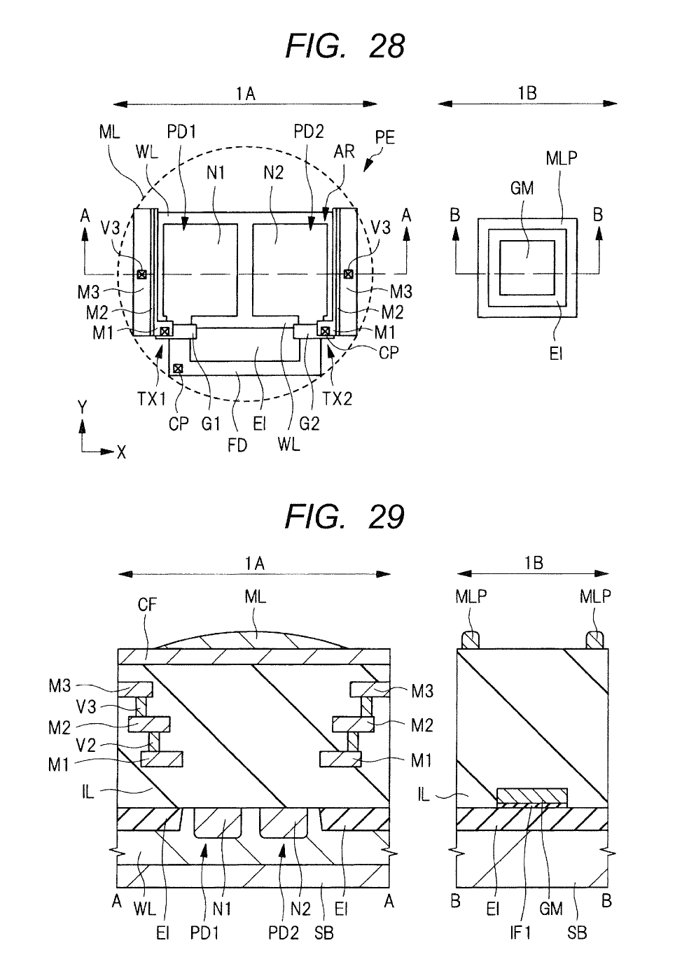

In a third embodiment of the present invention, a gate pattern formed between photodiodes as in the first embodiment is removed after the photodiodes are formed. FIGS. 27 and 28 are each a plan view of a semiconductor device in the process of being manufactured according to the third embodiment. FIG. 29 shows sectional views taken along lines A-A and B-B in FIG. 28. In each of FIGS. 27 to 29 like in FIGS. 16 and 17, a pixel area 1A and a check pattern area 1B are shown.

A solid-state image sensor including pixels in each of which a gate layer is formed near two photodiodes serving as photoelectric conversion parts has a problem that the gate layer becomes an optical shield to degrade the sensitivity of the solid-state image sensor. Polysilicon used as a gate electrode material absorbs light through photoelectric conversion. Particularly, when incident light is inclined, it does not reach portions shielded by the gate layer of the photodiodes, so that the sensitivity of the image sensor declines.

According to the present embodiment, on the other hand, the gate pattern G3 is formed in the process described with reference to FIGS. 5 and 6 (step S5 in FIG. 1), then the N⁻-type semiconductor regions N1 and N2 are self-alignedly formed using the gate pattern G3 as a mask. Subsequently, only the gate pattern G3 is exposed by newly performing lithography, and the gate pattern G3 is removed, as shown in FIG. 27, by dry etching or wet etching.

The semiconductor device manufacturing process according to the present embodiment includes a process for removing the gate pattern G3. In the other respects, it is the same as the semiconductor device manufacturing process according to the first embodiment. Hence, except that, as shown in FIGS. 28 and 29, the gate pattern G3 (see FIG. 16) is not formed in the semiconductor device of the present embodiment, the semiconductor device of the present embodiment is structured identically to the semiconductor device of the first embodiment. The gate pattern G3 is to be removed, at the latest, before the process (step S8 in FIG. 1) for forming the interlayer insulating film CL (see FIG. 11).

According to the present embodiment, the effects similar to those obtained in the first embodiment can be obtained.

According to the present embodiment, the gate pattern G3 formed between the photodiodes PD1 and PD2 is removed after the ion implantation process performed to form the N⁻-type semiconductor regions N1 and N2. Therefore, it does not occur that, when light incident to each pixel of a finished semiconductor device is inclined, the gate pattern G3 shades the photodiode PD1 or PD2 included in the pixel. Namely, the sensitivity of the solid-state image sensor can be prevented from declining, so that performance of the semiconductor device can be improved.

### Fourth Embodiment

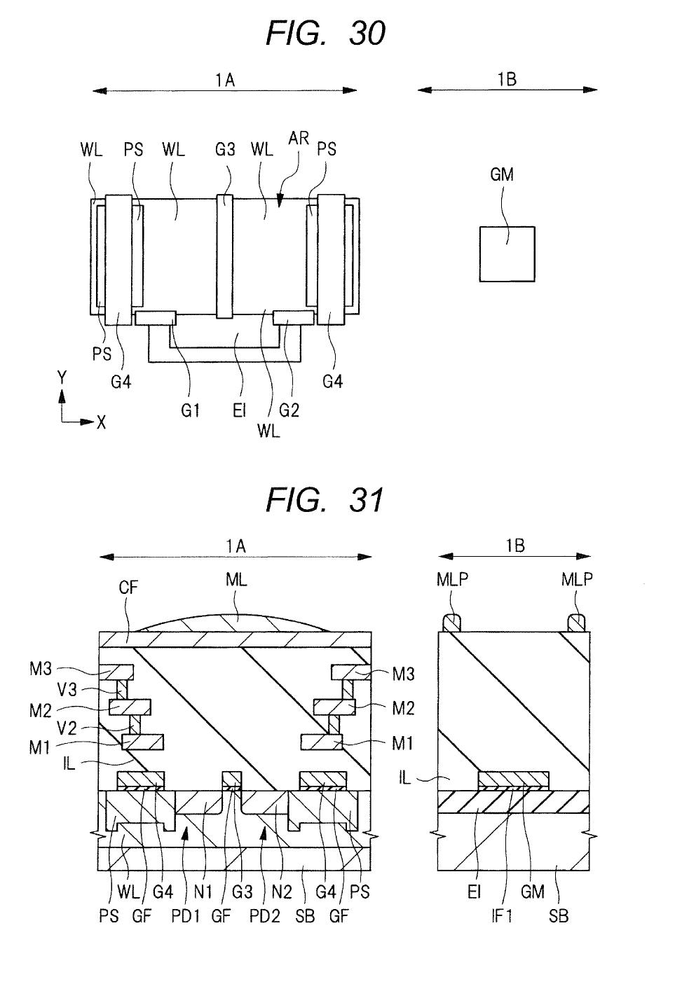

In a fourth embodiment of the present invention, ions for pixel isolation are implanted into semiconductor substrate portions near three gate patterns formed as in the foregoing second embodiment using a gate layer as a reference. FIGS. 30 and 31 are a plan view and a sectional view, respectively, of a semiconductor device in the process of being manufactured according to the present embodiment. In each of FIGS. 30 and 31 like in FIGS. 16 and 17, a pixel area 1A and a check pattern area 1B are shown.

In the present embodiment, implantation for interpixel isolation (step S4 in FIG. 1) described, without any illustration, in connection with the first embodiment is performed as shown in FIG. 30 after processes similar to the processes described with reference to FIGS. 2 to 6. In the present embodiment, gate patterns G4 are formed as in the foregoing second embodiment. FIG. 30 is a plan view showing a structure including P⁻ isolation regions PS formed, after forming a gate layer including gate electrodes G1 and G2, gate patterns G3 and G4, and check patterns GM, by implanting P-type impurities (e.g., boron (B)) of a relatively low concentration into prescribed regions by photolithography. The P⁻ isolation regions PS are formed using a gate layer (e.g., check patterns GM) as a reference. In the present embodiment, the P⁻ isolation regions PS are formed by implanting ions into the main surface of the semiconductor substrate portion including regions right under the gate patterns G4.

After the P⁻ isolation regions PS are formed as described above, processes similar to the processes described with reference to FIGS. 9 to 17 are performed to obtain the structure as shown in FIG. 31. In the present embodiment, the N⁻-type semiconductor regions N1 and N2 are self-alignedly formed in regions between, in the X direction, a pair of gate patterns G4, i.e. between a pair of P⁻ isolation regions PS.

The P⁻ isolation regions PS are formed by vertically implanting ions into the semiconductor substrate SB from above the gate patterns G4, so that, as shown in FIG. 31, the portion right below the gate pattern G4 of each P⁻ isolation region PS is shallower than other portions not covered by the gate pattern G4. Namely, the bottom portion right under the gate pattern G4 of each P⁻ isolation region PS is, as seen in a sectional view, concave away from the main surface of the semiconductor substrate SB. Thus, parts of the impurities implanted to form the P⁻ isolation regions PS are introduced into the semiconductor substrate SB through the gate patterns G4.

The P⁻ isolation regions PS including portions thereof which are formed right below the gate patterns G4 and are shallower than the other portions thereof are deeper than the N⁻-type semiconductor regions N1 and N2. This is because the photodiodes PD1 and PD2 formed, in each pixel, over the main surface of the semiconductor substrate SB require interpixel isolation. In the present embodiment, no element isolation region EI is formed right below each gate pattern G4.

The P⁻ isolation regions PS are isolation parts to prevent electrons generated by photoelectric conversion performed in each pixel from diffusing to adjacent pixels and to, thereby, improve sensitivity characteristics of the image sensor. Namely, the P⁻ isolation regions PS implanted with P-type impurities form potential barriers against electrons to prevent electrons from diffusing to adjacent pixels.

Unless P⁻ isolation implantation to form P⁻ isolation regions PS is performed at correct locations relative to the N⁻-type semiconductor regions N1 and N2, the output from one of the two photodiodes PD1 and PD2 becomes larger than the output from the other of the two photodiodes PD1 and PD2. This causes an output difference between the two photodiodes PD1 and PD2 even in a focused state, so that automatic focusing cannot be accurately performed.

According to the present embodiment, P⁻ isolation regions PS are formed by P⁻ isolation implantation using a gate layer as a reference, then N⁻-type semiconductor regions N1 and N2 are formed by implanting N-type impurities also using the gate layer as a reference. In this way, superposition misalignment between the P⁻ isolation regions PS and N⁻-type semiconductor regions N1 and N2 and the gate layer can be kept very small.

According to the present embodiment, the effects similar to those obtained in the foregoing second embodiment can be obtained.

### First Modification Example

In the following, a first modification example of the present embodiment will be described. The first modification example is a combination of the embodiment described with reference to FIGS. 30 and 31, the foregoing second embodiment, and the foregoing third embodiment. Namely, after the photodiodes are self-alignedly formed using the three gate patterns as masks, the three gate patterns in the light receiving part are removed, and then P⁻ isolation implantation is performed using the gate layer as a reference.

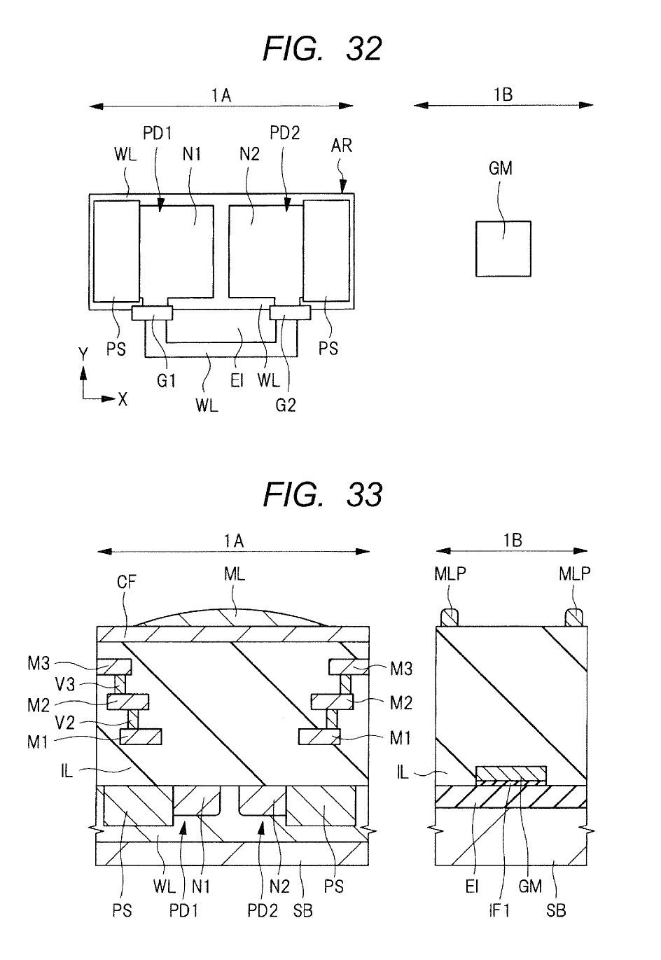

FIGS. 32 and 33 are a plan view and a sectional view, respectively, of a semiconductor device in the process of being manufactured according to the present embodiment. In each of FIGS. 32 and 33 like in FIGS. 16 and 17, a pixel area 1A and a check pattern area 1B are shown.

In the present modification example, first, processes similar to the processes descried with reference to FIGS. 2 to 6 are performed. In this case as in the foregoing second embodiment, the gate patterns G4 (see FIG. 25) are also formed in addition to the gate pattern G3. Also, the implantation process in step S4 shown in FIG. 1 is performed in a later process after the gate patterns G3 and G4 are removed. Subsequently, the implantation process described with reference to FIGS. 7 and 8 is performed. In the process, the photodiodes PD1 and PD2 are self-alignedly formed by ion implantation using the gate patterns G4 as a mask.

Next, the gate patterns G3 and G4 are selectively removed using a lithography technique and an etching method. Subsequently, a pair of P⁻ isolation regions PS are formed using a gate layer (e.g., check patterns GM) as a reference. The P⁻ isolation regions PS are semiconductor regions deeper than the N⁻ type semiconductor regions N1 and N2. In the present modification example, a pair of P⁻ isolation regions PS are formed in the active region AR to be on both sides in the X direction of the light receiving part that includes the N⁻ type semiconductor regions N1 and N2. The P⁻ isolation regions PS are larger in width in the Y direction than the N⁻ type semiconductor regions N1 and N2. With the P⁻ isolation regions PS formed, the photodiodes PD1 and PD2 are electrically isolated from the adjacent pixels.

In the present modification example unlike in the manufacturing process described with reference to FIG. 31, P⁻ isolation implantation is performed after the gate patterns G4 are removed. In this way, the structure shown in FIG. 32 can be obtained without causing the bottoms of the P⁻ isolation regions PS to become concave. Subsequently, the semiconductor device as shown in FIG. 33 is completed by performing processes similar to the processes described with reference to FIGS. 9-17.

According to the present modification example, effects similar to those obtained in the embodiment described with reference to FIGS. 30 and 31 can be obtained. For example, relative misalignment between the N⁻ type semiconductor regions N1 and N2, P⁻ isolation regions PS, and the respective gate layers can be prevented.

Also, according to the present modification example, the solid-state image sensor sensitivity can be prevented from declining due to shading by gate patterns.

### Second Modification Example

In the following, a second modification example of the present embodiment will be described. In the present modification example, without forming any gate pattern in the light receiving part, an N⁻ type semiconductor region is formed almost all over the light receiving part. Subsequently, P⁺ isolation implantation is performed to isolate the N⁻ type semiconductor region and define photodiodes.

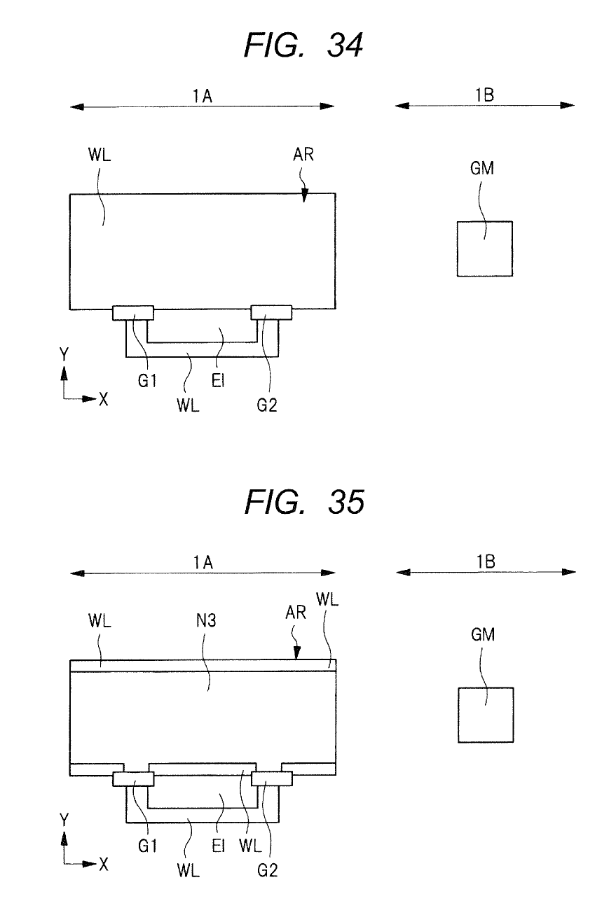

FIGS. 34 to 36 are plan views and FIG. 37 is a sectional view, each showing a semiconductor device in the process of being manufactured according to the present embodiment. In each of FIGS. 34 to 37 like in FIGS. 16 and 17, a pixel area 1A and a check pattern area 1B are shown.

In the present modification example, first, as shown in FIG. 34, processes similar to the processes descried with reference to FIGS. 2 to 6 are performed. In the present modification example, the gate electrodes G1 and G2 and the check patterns GM are formed without forming the gate pattern G3 (see FIG. 5) and gate patterns G4 (see FIG. 25).

Next, as shown in FIG. 35, an N⁻ type semiconductor region N3 extending in the X direction is formed in a region forming a light receiving part in the active region AR. The N⁻ type semiconductor region N3 is formed, for example, to range, without being divided, from one end portion to the other end portion in the X direction of the active region AR. The N⁻ type semiconductor region N3 like the N⁻ type semiconductor regions N1 and N2 (see FIG. 8) is a semiconductor region to be parts of photodiodes. Parts of the N⁻ type semiconductor region N3 are formed over the upper surfaces of semiconductor substrate SB portions adjoining the gate electrodes G1 and G2. Namely, the N⁻ type semiconductor region N3 ranges over most of the region forming the light receiving part of the active region AR.

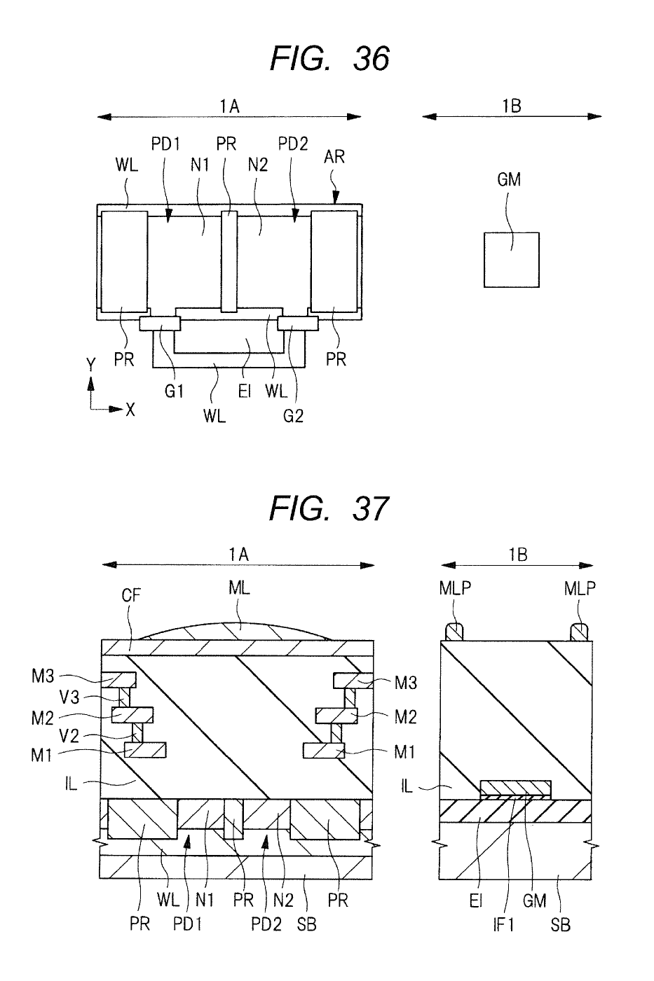

Next, as shown in FIG. 36, three P⁺ isolation regions PR each extending in the Y direction are formed in the active region AR by forming photoresist patterns using a gate layer (e.g., check patterns GM) as a reference and performing P⁺ isolation implantation. Namely, using the photoresist patterns formed by using a gate layer (e.g., check patterns GM) as a reference, ion implantation is performed to implant P-type impurities (e.g., boron (B)) of a relatively high concentration into the main surface of the semiconductor substrate SB. In this way, the three P⁺ isolation regions PR arranged in the X direction with each extending in the Y direction are formed.

Of the three P⁺ isolation regions PR, two are formed to be on both sides in the X direction of the N⁻ type semiconductor region N3 (see FIG. 35) and the remaining one is formed to be in the center in the X direction of the N⁻ type semiconductor region N3. In this way, in the N⁻ type semiconductor region N3, the N⁻ type semiconductor regions N1 and N2 are defined based on a predetermined layout.

Namely, of the three P⁺ isolation regions PR, the one in the center in the X direction is located to isolate the N⁻ type semiconductor regions N1 and N2 from each other. The other two P⁺ isolation regions PR are located to define the outer sides in the X direction of the N⁺ type semiconductor regions N1 and N2, respectively, and also to isolate the present pixel from the adjacent pixels. Thus, the N⁻ type semiconductor regions N1 and N2 are defined and the photodiodes PD1 and PD2 are formed by forming the P⁺ isolation regions PR as described above.

Subsequently, the semiconductor device as shown in FIG. 37 is completed by performing processes similar to the processes described with reference to FIGS. 9 to 17.

The above P⁺ isolation implantation is performed to define the layout of the photodiodes PD1 and PD2, to isolate the photodiodes PD1 and PD2 from each other, to prevent the electrons generated by photoelectric conversion performed in the pixel from diffusing to the adjacent pixels, and to eventually improve sensitivity characteristics of the solid-state mage sensor.

There is, however, a problem. For example, if, in addition to the P⁺ isolation implantation, the lithography process and ion implantation for forming the N⁻ type semiconductor regions N1 and N2 are also performed, the P⁺ isolation regions PR and the N⁻ type semiconductor regions N1 and N2 can be misaligned to cause the output from one of the two photodiodes PD1 and PD2 to become larger than the output of the other of the two photodiodes PD1 and PD2. This causes an output difference between the two photodiodes PD1 and PD2 even in a focused state, so that automatic focusing cannot be accurately performed.

According to the present modification example, the N⁻-type semiconductor regions N1 and N2 are defined by forming P⁺ isolation regions PR using a gate layer as a reference after the N⁻ type semiconductor region N3 (see FIG. 35) is formed in the large active region AR. In this way, misalignment of the P⁺ isolation regions PR and N⁻-type semiconductor regions N1 and N2 relative to the gate layer can be inhibited. Furthermore, by forming the microlens ML using gate-layer superposition control patterns, i.e. using the check patterns GM as references, superposition misalignment between the microlens ML and the P⁺ isolation regions PR and N⁻-type semiconductor regions N1 and N2 can be inhibited.

The P⁺ isolation implantation performed to define the layout of photodiodes as in the present modification example is not for interpixel isolation. It is applicable to regions peripheral to N⁻-type semiconductor regions forming photodiodes. In that case, superposition misalignment between the P⁺ isolation regions and the N⁻-type semiconductor regions can be reduced, so that the difference in output between the two photodiodes formed in the pixel can be reduced.

### Fifth Embodiment

In a fifth embodiment of the present invention, the two photodiodes formed in a pixel are isolated from each other by an element isolation region formed between them, and the location where the microlens is to be formed is checked and determined using superposition marks formed in the element isolation region.

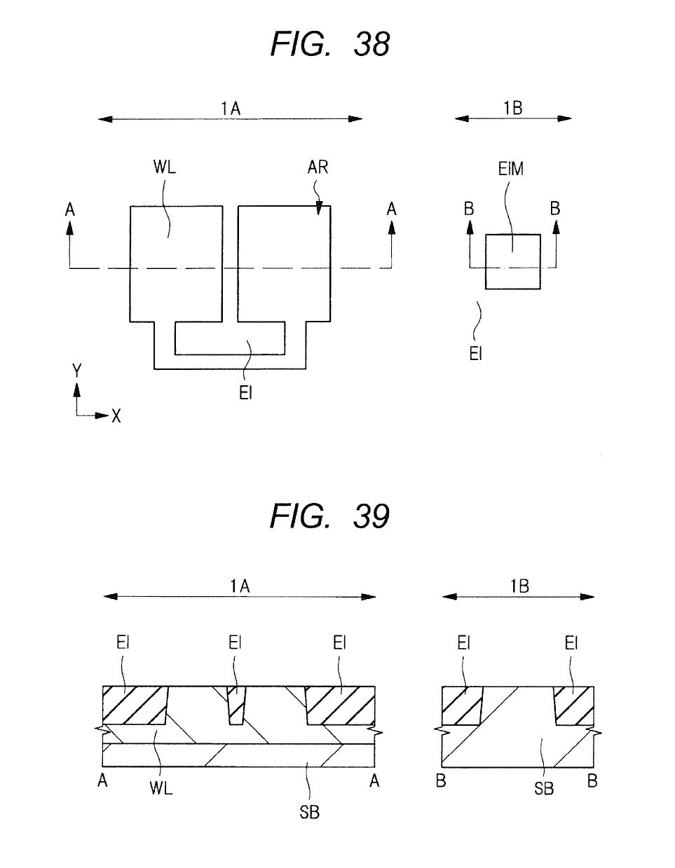

FIGS. 38, 40, 41, and 43 are plan views and FIGS. 39, 42, and 44 are sectional views, each showing a semiconductor device in the process of being manufactured according to the present embodiment. In each of FIGS. 38 to 44 like in FIGS. 16 and 17, a pixel area 1A and a check pattern area 1B are shown.

In the present embodiment, first, as shown in FIGS. 38 and 39, the processes described with reference to FIGS. 2 to 4 are performed. In the present embodiment, the region to form a light receiving part in the active region AR of the pixel area 1A is divided by an element isolation region EI. Namely, the active region AR does not have a rectangular ring structure. The element isolation region EI formed in this case has a depth of, for example, 500 nm or more from the main surface of the semiconductor substrate SB.

The active region AR is rectangular as seen in a plan view and includes two regions to form a light receiving part later. The two regions are adjacent to each other via the element isolation region EI in the X direction. The active region AR partly projects from two sides, other than the two opposing sides, of the two regions, and the two projecting parts of the active region AR are coupled to each other.

Also in the present embodiment, check patterns EIM are formed as superposition marks in the check pattern area 1B. Each check pattern EIM like the active region AR is a pattern defined by an element isolation region EI surrounding it. Namely, each check pattern EIM is formed of a main surface portion exposed from the element isolation region EI of the semiconductor substrate SB. The element isolation region EI defining each check pattern EIM is formed of a film of the same layer as the element isolation regions EI formed in the pixel area 1A. Namely, the check patterns EIM are element isolation patterns defined by the layout of the element isolation regions EI.

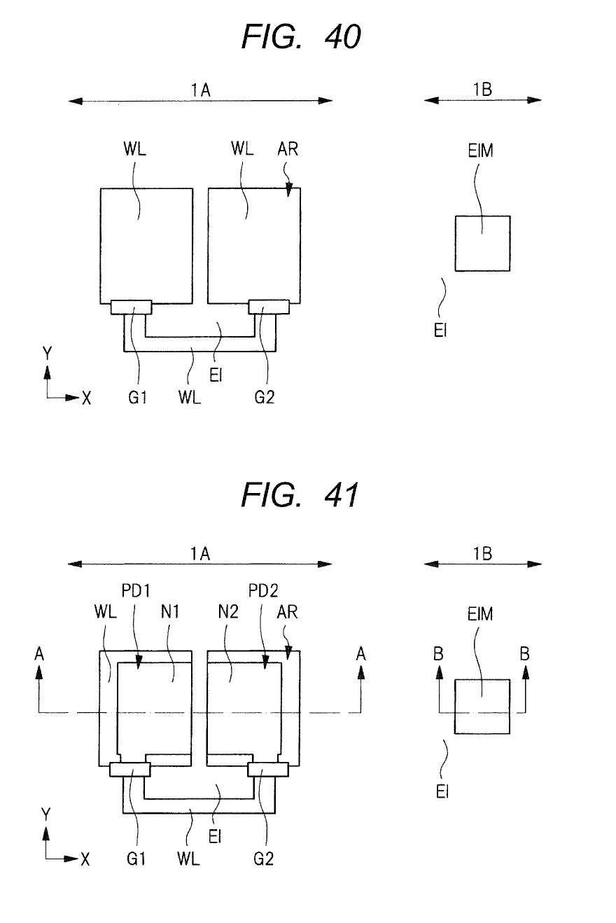

Next, as shown in FIG. 40, gate electrodes G1 and G2 are formed over the semiconductor substrate SB via a gate insulating film (not shown). The gate electrodes G1 and G2 are structured identically to those of the first embodiment. They form, in a later process, two transfer transistors. In the present embodiment, no check patterns of the same layer as the gate electrodes G1 and G2 are formed. Also, in the vicinity of the region forming the light receiving part, no gate patterns other than the gate electrodes G1 and G2 are formed of the same layer as the gate electrodes G1 and G2.

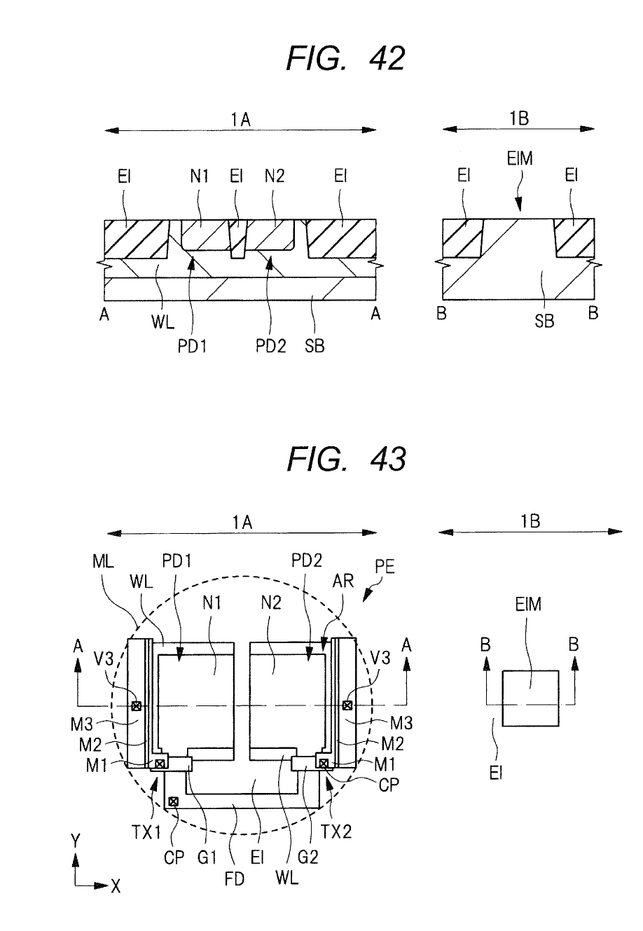

Next, as shown in FIGS. 41 and 42, N⁻-type semiconductor regions N1 and N2 are formed in the active region AR of the pixel area 1A using a photolithography technique and an ion implantation method using check patterns EIM as references. As a result, photodiode PD1 including the N⁻-type semiconductor region N1 and photodiode PD2 including the N⁻-type semiconductor region N2 are formed. The photodiodes PD1 and PD2 are isolated from each other by the element isolation region EI.

The N⁻-type semiconductor regions N1 and N2 oppose each other in the X direction. The sides opposing each other of the N⁻-type semiconductor regions N1 and N2 are both defined by the borders between the element isolation region EI and the active region AR. Thus, the sides opposing each other of the N⁻-type semiconductor regions N1 and N2 are self-alignedly formed relative to the element isolation region EI. Namely, in the present embodiment, the element isolation region EI dividing the active region AR is used as a mask in the ion implantation process for forming the N⁻-type semiconductor regions N1 and N2.

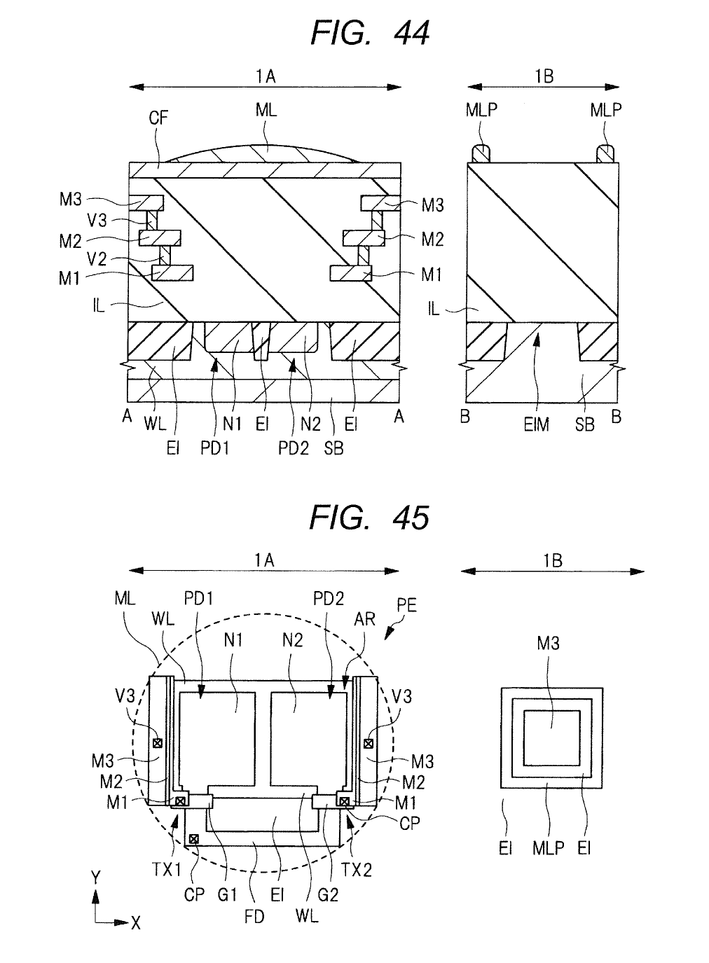

Next, as shown in FIGS. 43 and 44, by performing processes similar to the processes described with reference to FIGS. 9 to 17, the semiconductor device as shown in FIG. 37 is completed. In the present embodiment unlike in the first embodiment, the location where the microlens ML is to be formed is checked using as references the check patterns EIM defined by the element isolation region EI. As shown in FIG. 43, a check pattern MLP is formed to surround each check pattern EIM. Using these check patterns EIM and MLP for alignment of the microlens ML makes it possible to form the microlens ML without much misalignment relative to the element isolation region EI.

According to the present embodiment, in the ion implantation process for forming the photodiodes PD1 and PD2, the N⁻-type semiconductor regions N1 and N2 can be self-alignedly formed using the element isolation region EI as a mask such that the N⁻-type semiconductor regions N1 and N2 are defined by edge portions of the element isolation region EI. Namely, the sides opposite to each other of the photodiodes PD1 and PD2 are in contact with the element isolation region EI formed between them. According to the present embodiment, to prevent misalignment between the N⁻-type semiconductor regions N1 and N2 self-alignedly formed relative to the element isolation region EI and the microlens ML, the location where the microlens ML is to be formed is checked and determined based on the check patterns EIM defined by the element isolation region EI.

Thus, the N⁻-type semiconductor regions N1 and N2 and the microlens ML are formed using the element isolation region EI as a reference. Therefore, according to the present embodiment compared with cases in which the N⁻-type semiconductor regions N1 and N2 are formed using the element isolation region EI as a reference whereas the microlens ML is formed using the gate layer or an upper layer wiring as a reference, misalignment between the N⁻-type semiconductor regions N1 and N2 and the microlens ML can be reduced. This improves focusing accuracy when automatic focusing is made using a solid-state image sensor. As a result, performance of the semiconductor device is improved.

Also, without any gate pattern formed between the photodiodes PD1 and PD2 in the present embodiment, no gate pattern shades light incident to pixels. This prevents the sensitivity of the solid-state image sensor from declining due to shading.

The implantation of P-type impurities performed for pixel isolation, etc. in the foregoing fourth embodiment may be performed after forming trenches for burying element isolation regions EI or after forming element isolation regions EI.

The invention made by the present inventors has been described in concrete terms based on embodiments, but the invention is not limited to the embodiments. The invention can be modified in various ways without departing from the scope thereof.

The following represents parts of the description of the foregoing embodiments.

(1) A semiconductor device manufacturing method for manufacturing a semiconductor device having a solid-state image sensor provided with a pixel which includes a first photodiode, a second photodiode, and a lens includes the following steps (a) to (f). In step (a), a substrate having a first area and a second area over an upper surface thereof is prepared. In step (b), a well region of a first conductivity type is formed over an upper surface of the substrate in the first area. In step (c), a first semiconductor region of a second conductivity type different from the first conductivity type is formed over the upper surface of the substrate in the first area. In step (d), a gate layer is formed over the substrate in the second area. In step (e), after the step (c), a first photodiode and a second photodiode are formed over the upper surface of the substrate in the first area. This is done by forming a second semiconductor region, a third semiconductor region, and a fourth semiconductor region of the first conductivity type over the upper surface of the substrate in the first area such that the second to fourth semiconductor regions are arranged in a prescribed direction at locations determined using the gate layer as a reference. The first photodiode includes a first portion of the first semiconductor region, the first portion being defined by the second semiconductor region and the third semiconductor region. The second photodiode includes a second portion of the first semiconductor region, the second portion being defined by the third semiconductor region and the fourth semiconductor region. In step (f), after the step (e), a wiring layer is formed over the substrate. In step (g), the lens is formed, over the wiring layer, at a location determined using the gate layer as a reference. The first semiconductor region is formed to be shallower than the second to fourth semiconductor regions.

(2) A semiconductor device which has a solid-state image sensor provided with a pixel including a first photodiode, a second photodiode, and a lens includes: a substrate having a first area and a second area over an upper surface thereof; a first element isolation region formed over the substrate in the first area; the first photodiode and the second photodiode formed over the upper surface of the substrate in the first area to adjoin the first element isolation region on both sides of the first element isolation region, respectively; an element isolation pattern formed over the substrate in the second area; a wiring layer formed over each of the first element isolation region and the element isolation pattern; the lens formed over the wiring layer in the first area; and a check pattern formed over the wiring layer in the second area to surround the element isolation pattern as seen in a plan view. In the semiconductor device: the element isolation pattern is defined by a second element isolation region of the same layer as the first element isolation region; and the lens and the check pattern are formed of film of a same layer.

What is claimed is:

1. A semiconductor device manufacturing method for manufacturing a semiconductor device having a solid-state image sensor provided with a pixel including a first photodiode, a second photodiode, and a lens, the method comprising the steps of:
(a) preparing a substrate having a first area and a second area over an upper surface thereof;
(b) forming a well region of a first conductivity type over an upper surface of the substrate in the first area;
(c) forming a first gate layer over the substrate in the first area and a second gate layer over the substrate in the second area;
(d) forming the first photodiode and the second photodiode to be beside the first gate layer over the upper surface of the substrate in the first area by implanting impurities into the upper surface of the substrate in the first area using the first gate layer as a mask, the first photodiode and the second photodiode including a first semiconductor region of a second conductivity type different from the first conductivity type;
(e) after the step (d), forming a wiring layer over the substrate; and
(f) over the wiring layer, forming the lens in a location determined using the second gate layer as a reference,
wherein, in the step (d), the first photodiode and the second photodiode are formed on both sides of the first gate layer, respectively, as seen in a plan view.

2. The semiconductor device manufacturing method according to claim 1,
wherein, in the step (c), the second gate layer, a pair of third gate layers, and the first gate layer located between the third gate layers are formed in the first area, and
wherein, in the step (d), using the first gate layer and the third gate layers as masks, the first photodiode is formed between the first gate layer and one of the third gate layers and the second photodiode is formed between the first gate layer and the other of the third gate layers.

3. The semiconductor device manufacturing method according to claim 1, further comprising a step of:
(d1) after the step (d), removing the first gate layer.

4. The semiconductor device manufacturing method according to claim 2, further comprising a step of:
(c1) before the step (d), forming a pair of second semiconductor regions of the first conductivity type over the upper surface of the substrate in the first area by implanting impurities into the upper surface of the substrate in the first area including a region right under each of the third gate layers such that the second semiconductor regions are located side by side on both sides of a region right under the first gate layer,
wherein, in the step (d), the first photodiode and the second photodiode are formed between the second semiconductor regions,
wherein, in the step (c1), the second semiconductor regions are formed at locations determined using the second gate layer as a reference,
wherein the second semiconductor regions are formed to be deeper than the first semiconductor region, and
wherein a bottom portion right under one of the third gate layers of each of the second semiconductor regions is concave away from the upper surface of the substrate.

5. The semiconductor device manufacturing method according to claim 2, further comprising the steps of:
(d2) after the step (d), removing the first gate layer; and
(d3) after the step (d2), forming a pair of second semiconductor regions of the first conductivity type over the upper surface of the substrate in the first area by implanting impurities into the upper surface of the substrate in the first area,
wherein the second semiconductor regions are formed such that, in the direction in which the first photodiode and the second photodiode are arranged, the second semiconductor regions are on both sides, respectively, of the first photodiode and the second photodiode,
wherein, in the step (d3), the second semiconductor regions are formed at locations determined using the second gate layer as a reference, and
wherein the second semiconductor regions are formed to be deeper than the first semiconductor region.

6. The semiconductor device manufacturing method according to claim 1,
wherein the solid-state image sensor includes a pixel array part in which a plurality of the pixels are arranged, and
wherein a plurality of the second gate layers are located outside the pixel array part.

7. The semiconductor device manufacturing method according to claim 1,
wherein no wiring is formed right over the second gate layers.

8. The semiconductor device manufacturing method according to claim 1,
wherein the solid-state image sensor performs automatic focusing by a focus detection method based on image plane phase difference detection.

9. The semiconductor device manufacturing method according to claim 1,
wherein, in the step (d), locations where the first and second photodiodes other than sides thereof to be in contact with the first gate layer are to be formed are determined using the second gate layers as references.

10. A semiconductor device manufacturing method for manufacturing a semiconductor device having a solid-state image sensor provided with a pixel including a first photodiode, a second photodiode, and a lens, the method comprising the steps of:
(a) preparing a substrate having a first area and a second area over an upper surface thereof;
(b) forming a well region of a first conductivity type over an upper surface of the substrate in the first area;
(c) forming an element isolation region over the substrate in the first area and an element isolation pattern over the substrate in the second area;
(d) forming the first photodiode and the second photodiode to be beside the element isolation region over the upper surface of the substrate in the first area by implanting impurities into the upper surface of the substrate in the first area using the element isolation region as a mask, the first photodiode and the second photodiode including a first semiconductor region of a second conductivity type different from the first conductivity type;
(e) after the step (d), forming a wiring layer over the substrate; and
(f) over the wiring layer, forming the lens in a location determined using the element isolation pattern as a reference,
wherein, in the step (d), the first photodiode and the second photodiode are formed on both sides of the element isolation region, respectively, as seen in a plan view.

11. A semiconductor device having a solid-state image sensor provided with a pixel including a first photodiode, a second photodiode, and a lens, the semiconductor device comprising:
a substrate having a first area and a second area over an upper surface thereof;
a well region of a first conductivity type formed over an upper surface of the substrate in the first area;
a first gate layer formed over the substrate in the first area;
the first photodiode and the second photodiode formed over the upper surface of the substrate in the first area to adjoin the first gate layer on both sides of the first gate layer, respectively;
a second gate layer formed over the substrate in the second area;
a wiring layer formed over each of the first gate layer and the second gate layer;
the lens formed over the wiring layer in the first area; and
a check pattern formed over the wiring layer in the second area to surround the second gate layer as seen in a plan view,
wherein the first photodiode and the second photodiode each have a first semiconductor region of a second conductivity type different from the first conductivity type,
wherein the first gate layer and the second gate layer are formed of film of a same layer, and
wherein the lens and the check pattern are formed of film of a same layer.

12. The semiconductor device according to claim 11, further comprising a pair of third gate layers formed in the first area such that, in the direction in which the first photodiode, the first gate layer, and the second photodiode are formed side by side, the first photodiode and the second photodiode are located between the third gate layers,
wherein one of the third gate layers adjoins the first photodiode and the other of the third gate layers adjoins the second photodiode.

13. The semiconductor device according to claim 12, further comprising a second semiconductor region of the first conductivity type formed over the upper surface of the substrate right under each of the third gate layers,
wherein the second semiconductor regions are formed to be deeper than the first semiconductor region of the second conductivity type different from the first conductivity type, the first semiconductor region including the first photodiode and the second photodiode, and
wherein a bottom portion right under one of the third gate layers of each of the second semiconductor regions is concave away from the upper surface of the substrate.

14. The semiconductor device according to claim 11,
wherein the solid-state image sensor includes a pixel array part in which a plurality of the pixels are arranged, and
wherein a plurality of the second gate layers are located outside the pixel array part.

15. The semiconductor device according to claim 11,
wherein no wiring is formed right over the second gate layers.

16. The semiconductor device according to claim 11,
wherein the solid-state image sensor performs automatic focusing by a focus detection method based on image plane phase difference detection.
